(19) United States
(12) Patent Application Publication
(10) Pub. No.: US 2025/0393234 A1
(43) Pub. Date: Dec. 25, 2025

(54) SEMICONDUCTOR DEVICES HAVING SEAM-ISOLATING STRUCTURES AND METHODS FOR MANUFACTURING THE SAME

(71) Applicant: Taiwan Semiconductor Manufacturing Company, Ltd., Hsinchu (TW)

(72) Inventor: Tzu-Ging Lin, Kaohsiung (TW)

(73) Assignee: Taiwan Semiconductor Manufacturing Company, Ltd., Hsinchu (TW)

(21) Appl. No.: 18/750,024

(22) Filed: Jun. 21, 2024

(51) Int. Cl. H01L 29/66; H01L 21/8234; H01L 27/088; H01L 29/78

(52) U.S. Cl. CPC H10D 30/024; H10D 30/62; H10D 84/0149; H10D 84/0151; H10D 84/0158; H10D 84/038; H10D 84/834

(57) ABSTRACT

Semiconductor devices and methods for manufacturing the same are provided. The semiconductor devices include a substrate, a fin overlying the substrate and providing active regions for at least two devices, a fin-insulating structure positioned to electrically isolate the active regions for the at least two devices, wherein the fin-insulating structure extends through the fin and into the substrate, wherein the fin-insulating structure includes a dielectric material, and a pair of seam-isolating structures positioned adjacent to the fin on oppositely disposed sides thereof, wherein the seam-isolating structures define boundaries of the fin-insulating structure on the sides of the fin.

### BACKGROUND

The semiconductor integrated circuit (IC) industry has continued its rapid growth in recent years. Technological advancements in IC materials and design have led to continuous improvements in the generations of ICs. With each new generation, the circuits become smaller and more complex than their predecessors, resulting in higher functional density (i.e., the number of interconnected devices per chip area) and smaller geometric sizes (i.e., the smallest component or line that can be created using a fabrication process). This scaling down process has been beneficial in increasing production efficiency and reducing associated costs. However, as feature sizes continue to shrink, the manufacturing process becomes more challenging, and it becomes increasingly difficult to ensure the reliability of semiconductor devices. As a result, the industry faces the ongoing challenge of developing processes that can create smaller, more reliable ICs.

### BRIEF DESCRIPTION OF DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a flowchart illustrating an exemplary method for forming a semiconductor structure in accordance with some embodiments;

FIGS. 2-45 schematically represent a first method of forming a semiconductor structure in accordance with some embodiments;

FIGS. 46-85 schematically represent a second method of forming a semiconductor structure in accordance with some embodiments;

FIG. 86 schematically represents a partial top view of a portion of a semiconductor device at one stage in an integrated circuit manufacturing process in accordance with some embodiments;

FIG. 87 schematically represents a partial top view of a portion of a semiconductor device at one stage in an integrated circuit manufacturing process in accordance with some embodiments; and

FIG. 88 schematically represents a perspective view of a portion of a semiconductor device at one stage in an integrated circuit manufacturing process in accordance with some embodiments.

### DETAILED DESCRIPTION

The following disclosure provides many different embodiments, or examples, for implementing different features of the provided subject matter. Specific examples of elements and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

As used herein, the terms such as “first,” “second” and “third” describe various elements, components, regions, layers and/or sections, but these elements, components, regions, layers and/or sections should not be limited by these terms. These terms may be only used to distinguish one element, component, region, layer or section from another. The terms such as “first,” “second” and “third” when used herein do not imply a sequence or order unless clearly indicated by the context.

For the sake of brevity, conventional techniques related to conventional semiconductor device fabrication may not be described in detail herein. Moreover, the various tasks and processes described herein may be incorporated into a more comprehensive procedure or process having additional functionality not described in detail herein. In particular, various processes in the fabrication of semiconductor devices are well-known and so, in the interest of brevity, many conventional processes will only be mentioned briefly herein or will be omitted entirely without providing the well-known process details. As will be readily apparent to those skilled in the art upon a complete reading of the disclosure, the structures disclosed herein may be employed with a variety of technologies, and may be incorporated into a variety of semiconductor devices and products. Further, it is noted that semiconductor device structures include a varying number of components and that single components shown in the illustrations may be representative of multiple components.

Furthermore, spatially relative terms, such as “over”, “overlying”, “above”, “upper”, “top”, “under”, “underlying”, “below”, “lower”, “bottom”, and the like, may be used herein for ease of description to describe one element's or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly. When a spatially relative term, such as those listed above, is used to describe a first element with respect to a second element, the first element may be directly on the other element, or intervening elements or layers may be present. When an element or layer is referred to as being “on” another element or layer, it is directly on and in contact with the other element or layer.

It is noted that references in the specification to “one embodiment,” “an embodiment,” “an example embodiment,” “exemplary,” “example,” etc., indicate that the embodiment described may include a particular feature, structure, or characteristic, but every embodiment may not necessarily include the particular feature, structure, or characteristic. Moreover, such phrases do not necessarily refer to the same embodiment. Further, when a particular feature, structure or characteristic is described in connection with an embodiment, it would be within the knowledge of one skilled in the art to affect such feature, structure, or characteristic in connection with other embodiments whether or not explicitly described.

Some embodiments of the disclosure will now be described with reference to the drawings, wherein like reference numerals are generally used to refer to like elements throughout. In the following description, for purposes of explanation, numerous specific details are set forth in order to provide a thorough understanding of the claimed subject matter. It is evident, however, that the claimed subject matter may be practiced without these specific details. In other instances, structures and devices are illustrated in block diagram form in order to facilitate describing the claimed subject matter.

Additional operations can be provided before, during, and/or after the stages described in these embodiments. Some of the stages that are described can be replaced or eliminated for different embodiments. Additional features can be added to the semiconductor device structure. Some of the features described below can be replaced or eliminated for different embodiments. Although some embodiments are discussed with operations performed in a particular order, these operations may be performed in another logical order.

As used herein, a “layer” is a region, such as an area comprising arbitrary boundaries, and does not necessarily comprise a uniform thickness. For example, a layer can be a region comprising at least some variation in thickness.

In semiconductor fabrication, self-aligning contact (SAC) processes are used to create contacts between metal interconnects and underlying semiconductor devices, such as transistors. A sacrificial material is often used in SAC processes to temporarily fill gaps between metal interconnects before the final contact formation. This sacrificial material is then removed, leaving behind self-aligned contacts. In advanced nodes with aggressive scaling requirements, SAC processes are desired to avoid leakage between metal gates and metal contacts connecting sources or drains.

Continuous metal on diffusion edge (CMODE) processes may be used wherein metal gates are extended on the edge of diffused regions. These processes may improve device performance and reduce parasitic resistance and capacitance. For purposes of this disclosure, a “diffusion edge” may be equivalently referred to as an active edge, where for example an active edge abuts adjacent active regions. Further, an active region includes a region where transistor structures are formed (e.g., including source/drain structures and gate/channel structures). In some examples, active regions may be disposed between insulating regions. The CMODE process may provide an isolation region between neighboring active regions, and thus neighboring transistors, by performing an etching process along an active edge (e.g., at a boundary of adjacent active regions) to form a cut region and filling the cut region with a refill material.

However, combining SAC processes and CMODE processes presents some challenges. For example, if the SAC sacrificial material includes seams extending therethrough, by-product materials of the etching process and/or the refill material may flow or diffuse into the seams connected to the cut region which can result in severe defects in the semiconductor device and an increased risk of leakage.

Presented herein are embodiments of semiconductor devices and of methods for forming semiconductor devices with combinations of SAC processes and CMODE processes. To reduce the likelihood of undesired material entry into seams of the SAC sacrificial material, the examples semiconductor devices disclosed herein include seam-isolating structures configured to seal line ends of the semiconductor devices. As used herein, a “line end” refers to a point where a metal gate line terminates or ends. Metal gates are conductive pathways made of metal (e.g., TiN, TiAl or W) that are patterned on the surface of a semiconductor device. These metal gates serve to turn on or turn off the transistors on the integrated circuit. In some examples, the seam-isolating structures are formed in the semiconductor devices prior to performing the SAC processes and/or the CMODE processes.

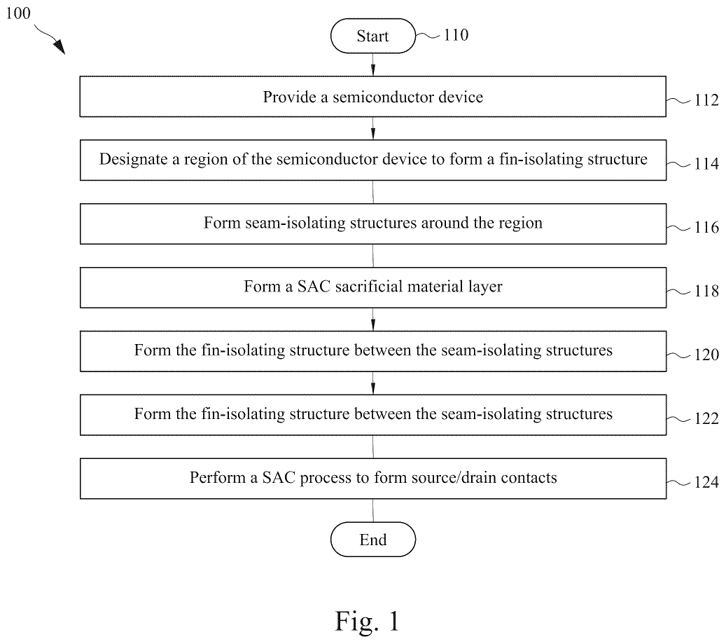

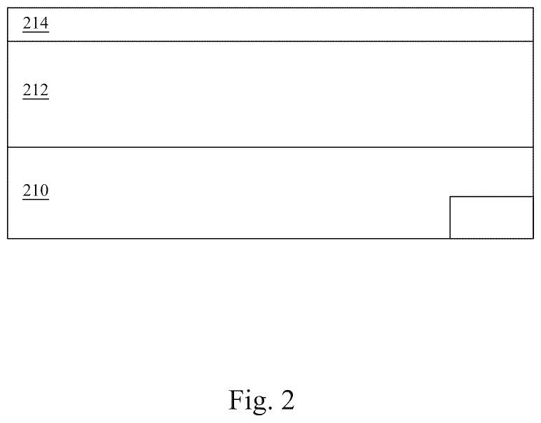

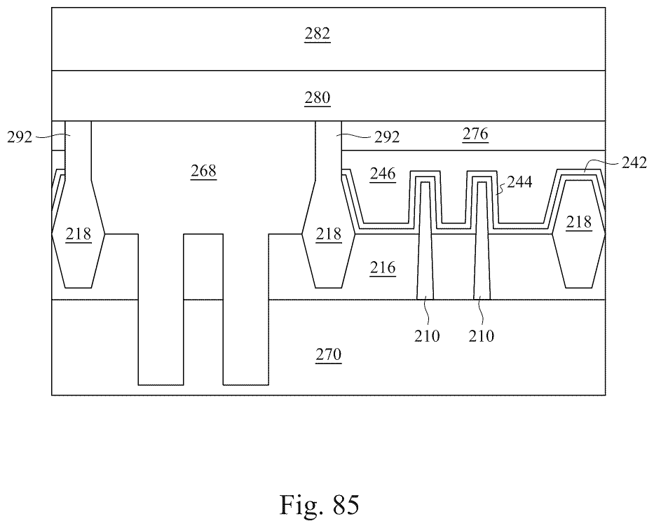

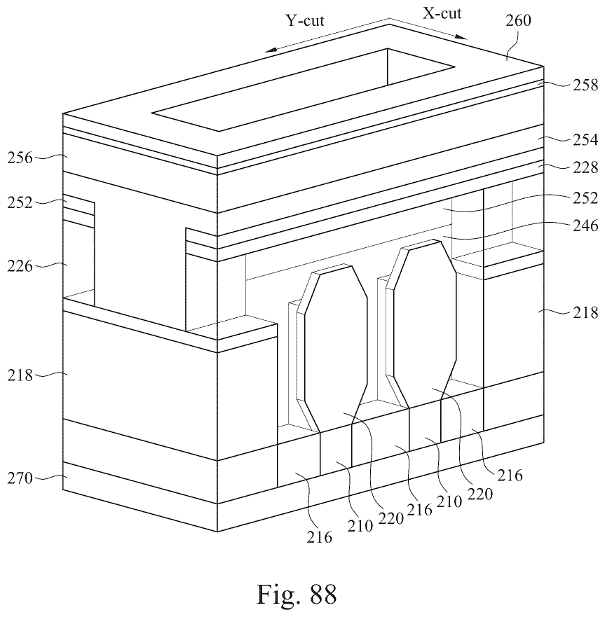

With reference to FIG. 1, a flowchart provides an exemplary method 100 for forming a semiconductor device in accordance with various examples. For example, at least some of the operations (or steps) of the method 100 can be used to form a fin field-effect transistor (FinFET) device, a gate-all-around (GAA) FET device, a nanosheet transistor device, a nanowire transistor device, a vertical transistor device, or the like. It is noted that the method 100 is merely an example, and is not intended to limit the present disclosure. Accordingly, it is understood that additional operations may be provided before, during, and after the method 100 of FIG. 1, and that some other operations may only be briefly described herein. For convenience, certain operations of the method 100 are described in reference to various views of exemplary semiconductor devices at various fabrication stages of an integrated circuit manufacturing process as shown in FIGS. 2-88. However, it will be understood that the semiconductor devices and the methods disclosed herein are not limited to the method 100 or the examples shown in FIGS. 2-88. In FIGS. 2-85, even numbered figures are cross-sectional views of the semiconductor structure from the x-cut perspective and odd numbered figures are cross-sectional views of the semiconductor structure from the y-cut perspective.

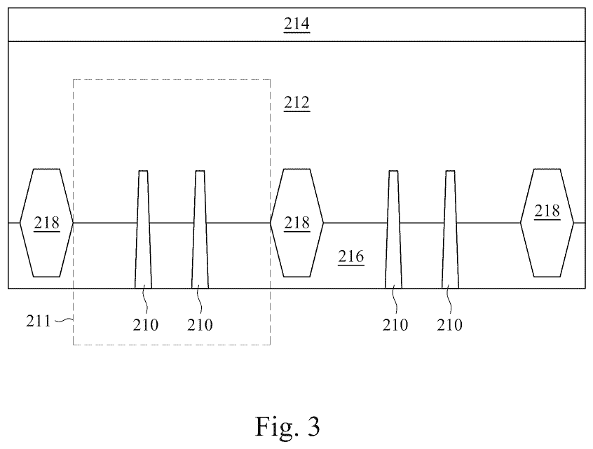

The method 100 may start at 110. At 112, the method 100 includes providing a semiconductor device at an intermediate stage of the manufacturing process. For convenience, semiconductor devices at various intermediate stages of the manufacturing process will be referred to herein as semiconductor structures. The semiconductor device may be any of a variety of types of semiconductor devices as mentioned previously. As an example, FIGS. 2 and 3 show cross-sectional views of a semiconductor structure at an intermediate stage during the manufacturing of a FinFET device along x and y directions, respectively (referred to as x-cut and y-cut in FIG. 88).

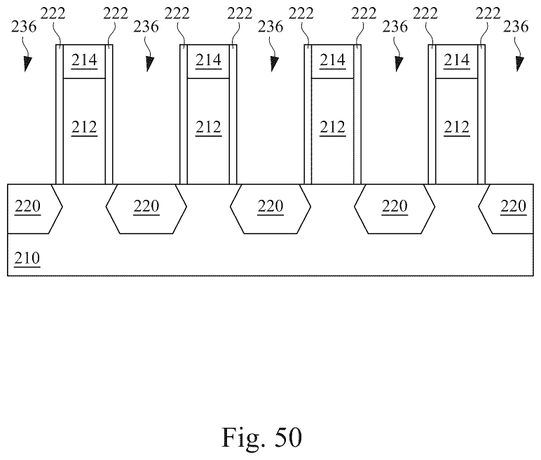

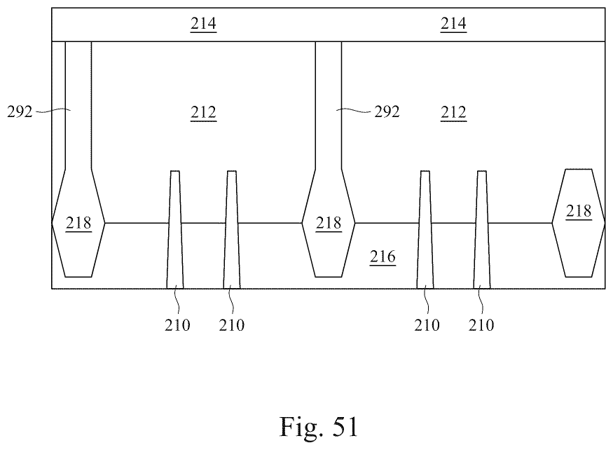

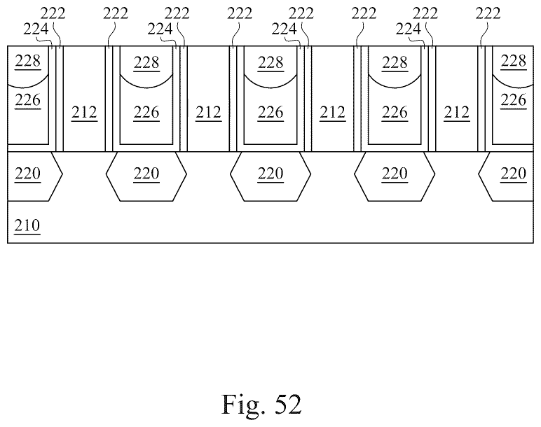

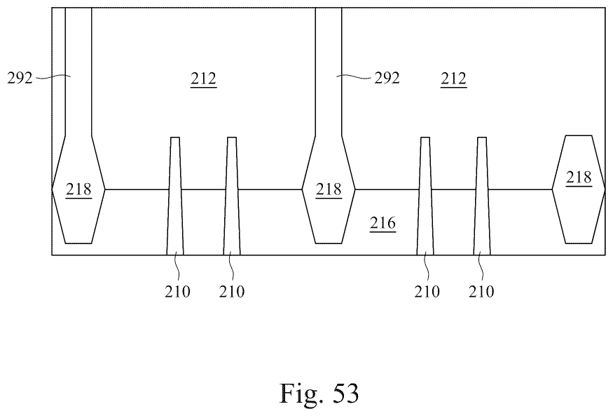

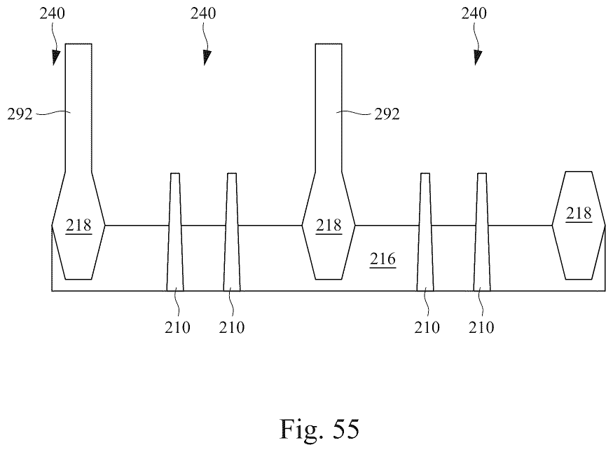

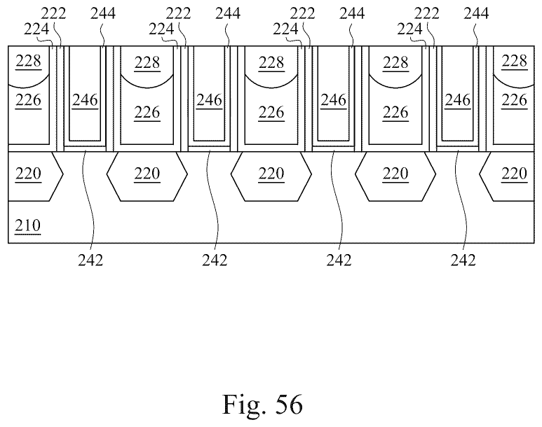

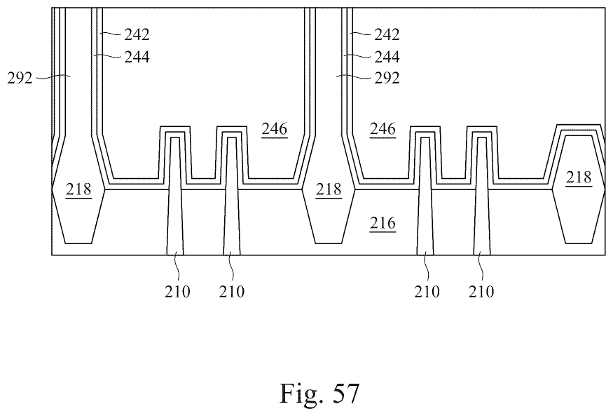

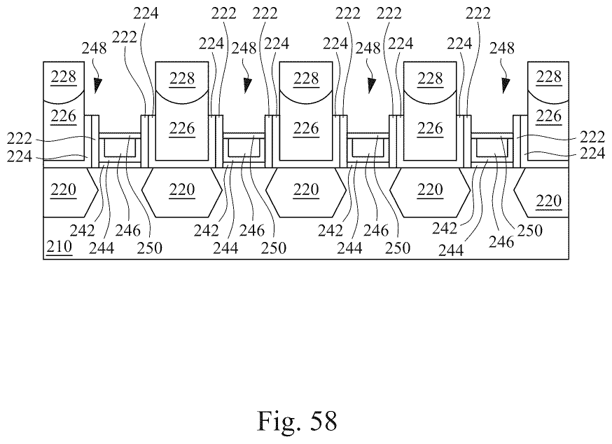

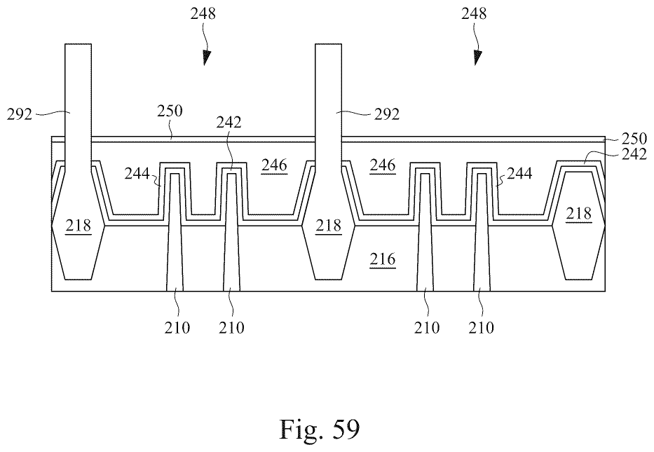

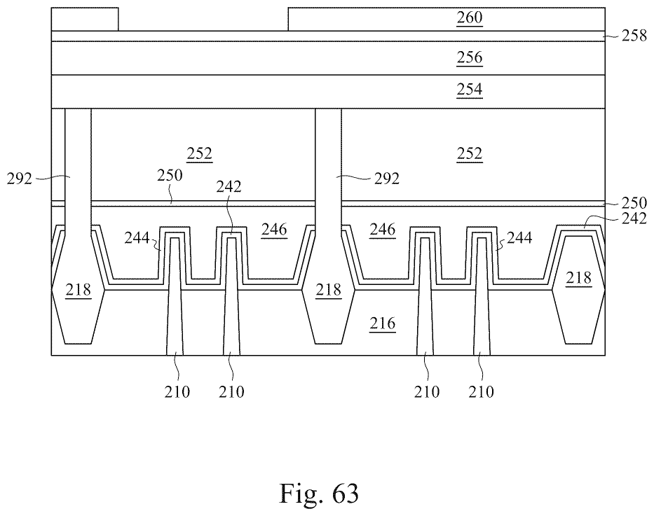

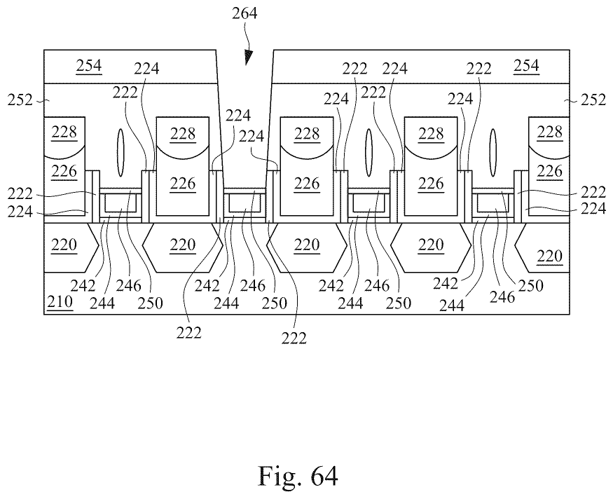

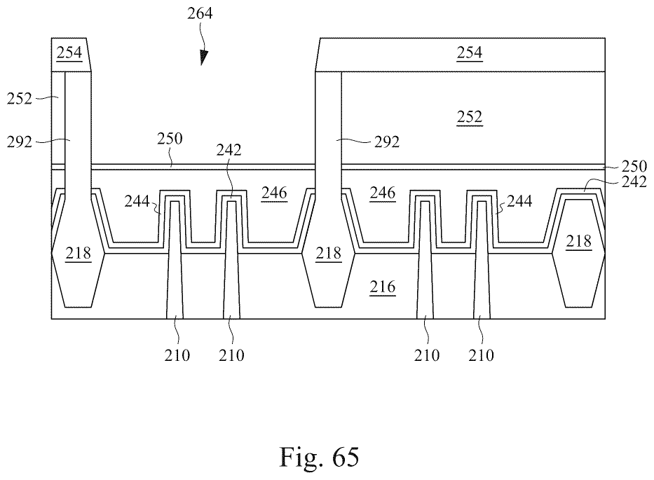

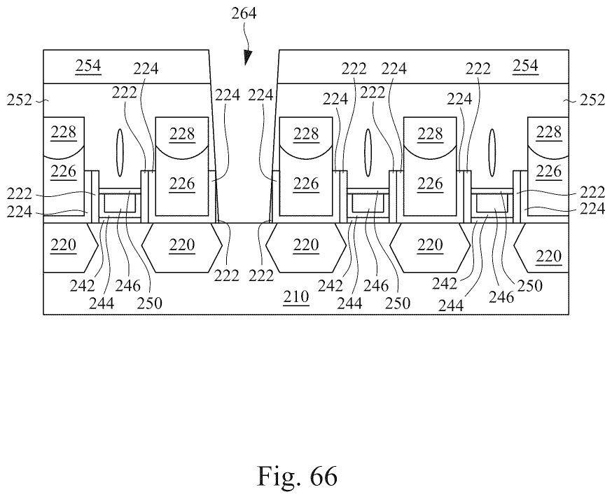

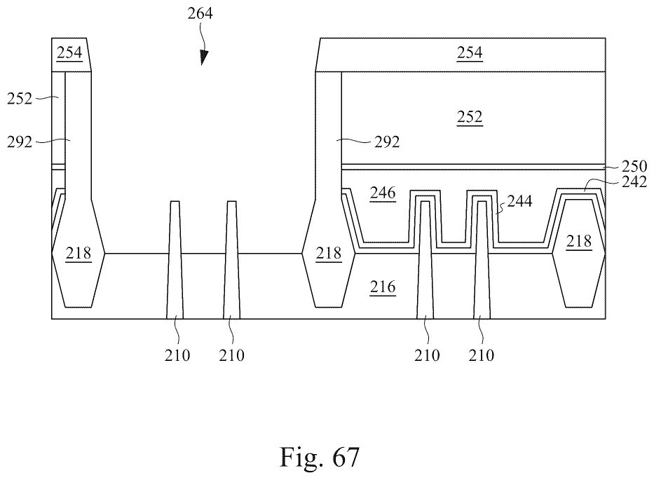

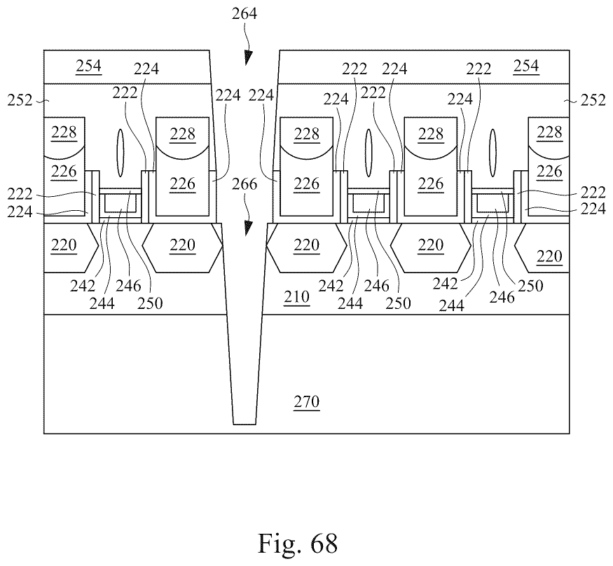

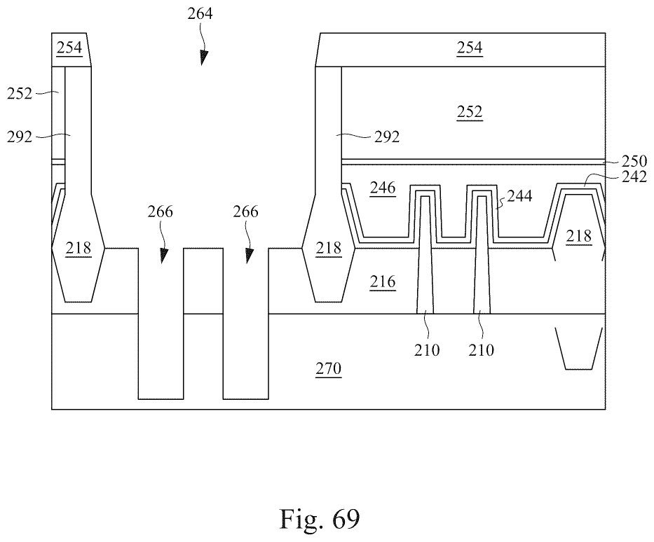

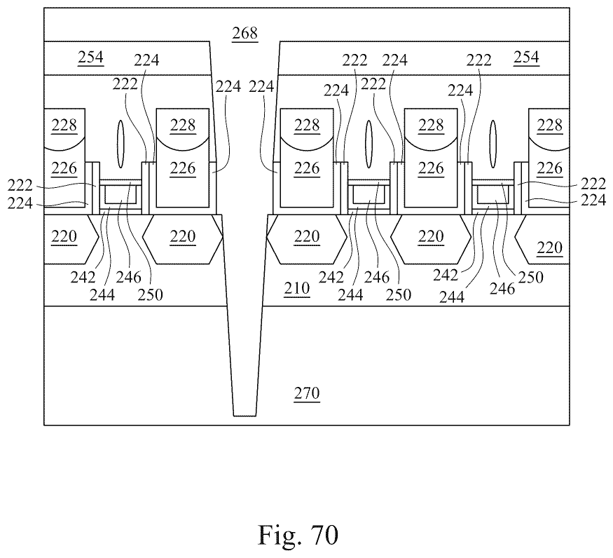

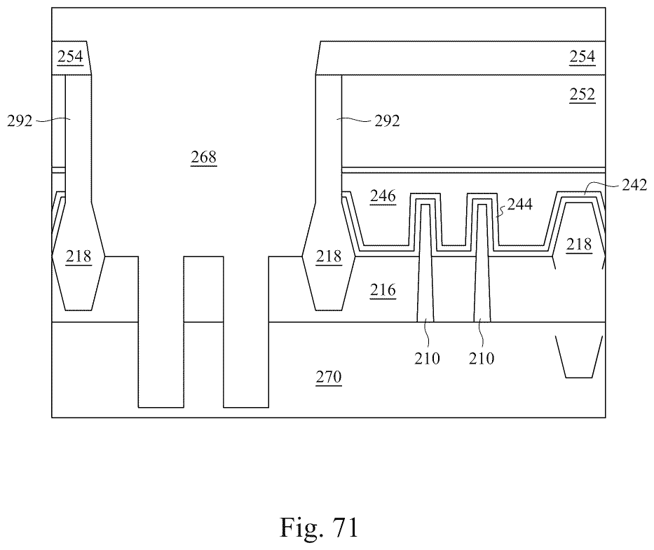

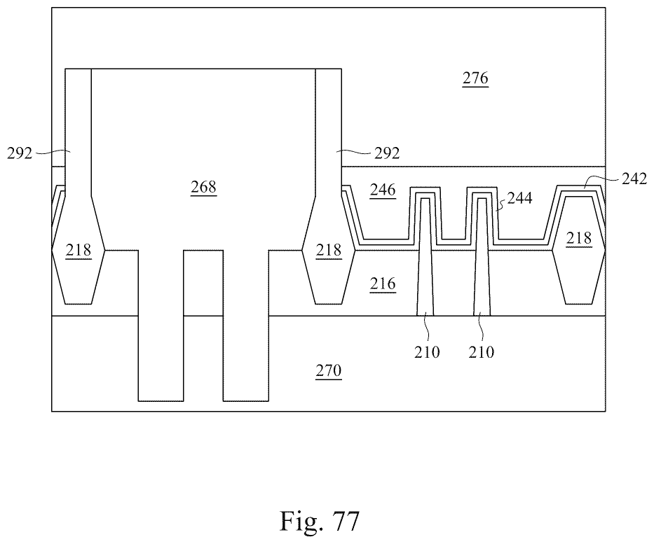

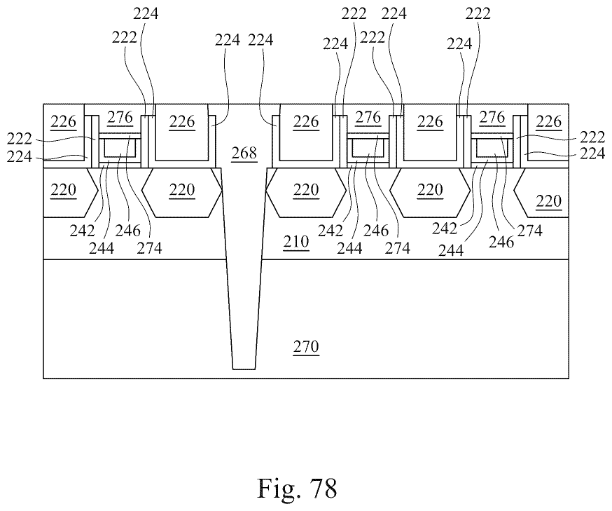

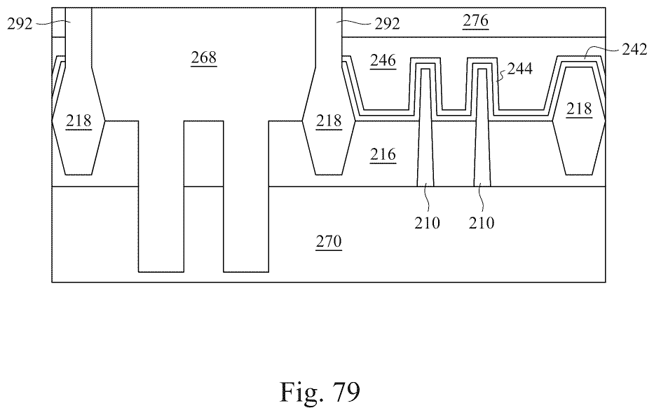

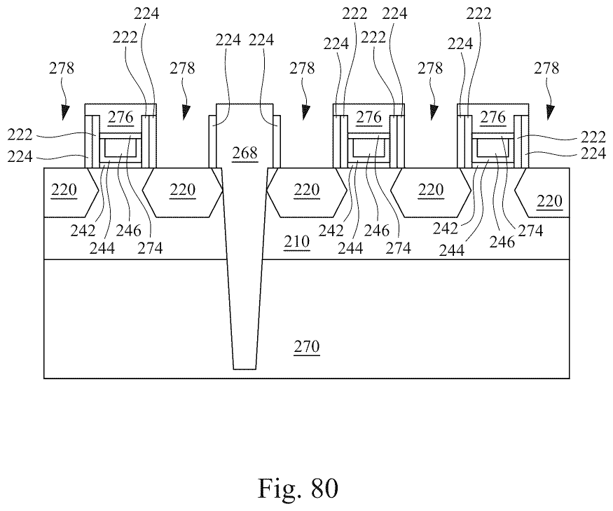

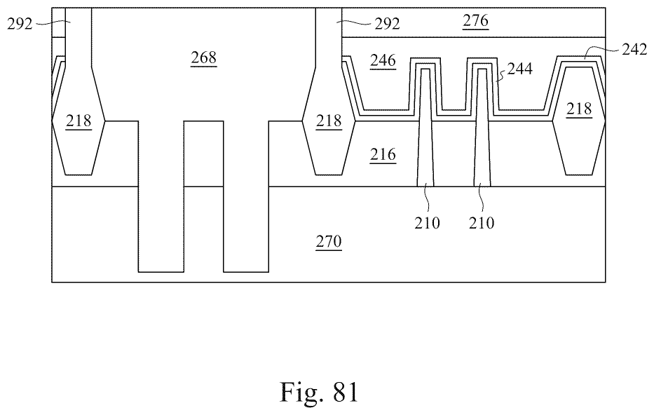

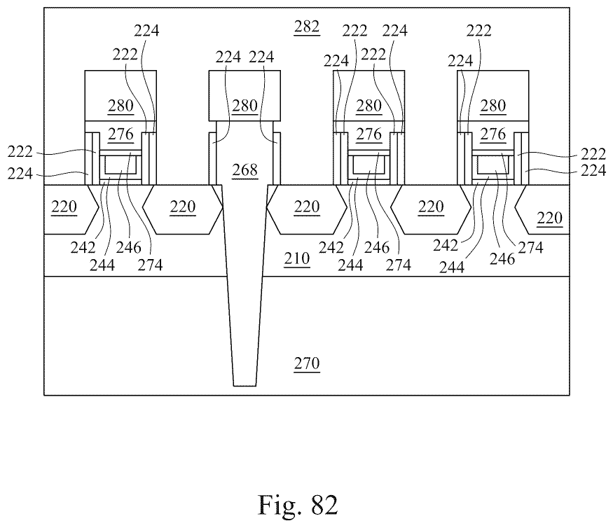

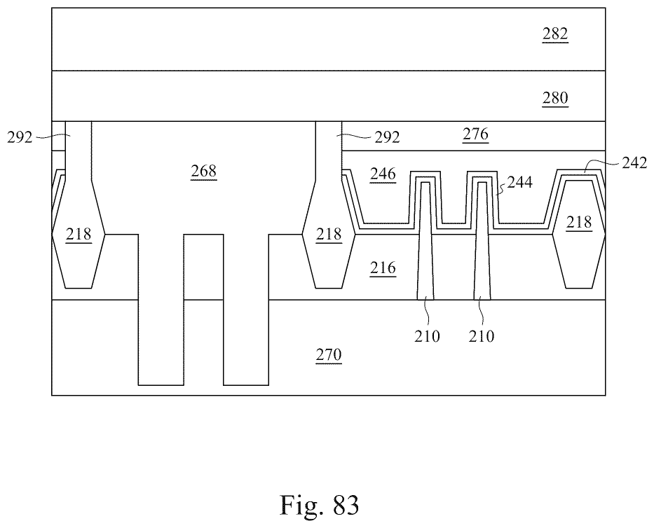

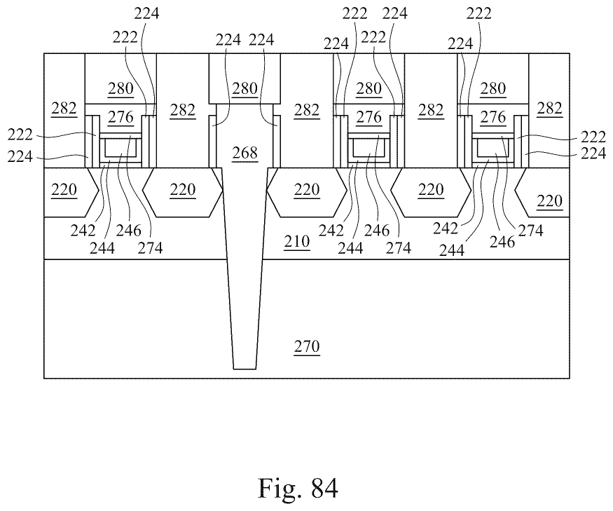

At the manufacturing stage represented in FIGS. 2 and 3, the semiconductor structure includes fin-type structures (fins) 210 extending from the substrate 270 (shown in FIGS. 50-85 and 88), through a shallow trench isolation (STI) 216 overlying the substrate 270, and into an dummy sacrificial gate layer 212 overlying the STI 216. Optionally, dummy fins 218 extend from the STI 216 and into the insulation layer 212. A hard mask layer 214 overlays the insulation layer 212.

The substrate 270 may be one of a variety of types of semiconductor substrates commonly employed in semiconductor integrated circuit fabrication, and integrated circuits may be formed therein and/or thereupon. The substrate 270 may be of any construction comprising semiconductor materials, including but not limited to, bulk silicon, a semiconductor wafer, a silicon-on-insulator (SOI) substrate, or a silicon germanium substrate. Other semiconductor materials, including group III, group IV, and/or group V semiconductors, can be used.

The fins 210 may be formed of one or more materials commonly employed for active fins in semiconductor devices. In some examples, the fins 210 may include certain conductive materials such as, but not limited to, silicon and silicon-based materials. In some examples, the fins 210 may be formed by various combinations of lithography and etching processes.

Lithography and etching processes discussed herein may include, for example, a mask layer (which can include multiple layers such as, for example, a pad oxide layer and an overlying pad nitride layer) may be formed over the layer to be modified (e.g., the substrate 270). The pad oxide layer may be a thin film comprising silicon oxide formed, for example, using a thermal oxidation process. The pad oxide layer may function as an adhesion layer between the layer to be modified and the overlying pad nitride layer. In some embodiments, the pad nitride layer is formed of silicon nitride, silicon oxynitride, silicon carbonitride, the like, or combinations thereof. The pad nitride layer may be formed using low-pressure chemical vapor deposition (LPCVD) or plasma enhanced chemical vapor deposition (PECVD), for example. The mask layer may be patterned using photolithography techniques. Generally, photolithography techniques utilize a photoresist material that is deposited, irradiated (exposed), and developed to remove a portion of the photoresist material. The remaining photoresist material protects the underlying material, such as the mask layer in this example, from subsequent processing steps, such as etching. For example, the photoresist material is used to pattern the pad oxide layer and pad nitride layer to form a patterned mask. Once the patterned mask is formed, an etching process may be used to etch the layer to be modified.

Etching processes discussed herein may include a plasma etching process, which can have a certain amount of anisotropic characteristic. In such a plasma etching process (including radical plasma etching, remote plasma etching, and other suitable plasma etching processes), gas sources such as chlorine (Cl₂), hydrogen bromide (HBr), carbon tetrafluoride (CF₄), fluoroform (CHF₃), difluoromethane (CH₂F₂), fluoromethane (CH₃F), hexafluoro-1,3-butadiene (C₄F₆), boron trichloride (BCl₃), sulfur hexafluoride (SF₆), hydrogen (H₂), nitrogen trifluoride (NF₃), hydrogen fluoride (HF), ammonia (NH₃), and other suitable gas sources and combinations thereof can be used with passivation gases such as oxygen (O₂), carbon dioxide (CO₂), sulfur dioxide (SO₂), carbon monoxide (CO), methane (CH₄), silicon tetrachloride (SiCl₄), and other suitable passivation gases and combinations thereof. Moreover, for the plasma etching process, the gas sources and/or the passivation gases can be diluted with gases such as argon (Ar), helium (He), neon (Ne), nitrogen (N₂), and other suitable dilutive gases and combinations thereof to control the above-described etching rates.

In another example, the etching processes discussed herein may include a wet etching process, which can have a certain amount of isotropic characteristic, in combination with the plasma etching process. In such a wet etching process, a main etch chemical such as hydrofluoric acid (HF), fluorine (F₂), and other suitable main etch chemicals and combinations thereof can be used with assistive etch chemicals such as sulfuric acid (H₂SO₄), hydrogen chloride (HCl), hydrogen bromide (HBr), ammonia (NH₃), phosphoric acid (H₃PO₄), and other suitable assistive etch chemicals and combinations thereof as well as solvents such as deionized water, alcohol, acetone, and other suitable solvents and combinations thereof to control the above-described etching rates.

The dummy sacrificial gate layer 212 may include various insulative materials such as, for example, silicon dioxide (SiO₂), silicon nitride (Si₃N₄), certain high-k dielectric materials (e.g., hafnium oxide (HfO₂) or aluminum oxide (Al₂O₃)), and polysilicon. In some examples, a thin layer of a silicon oxide-based dielectric material may be disposed between and to separate the dummy sacrificial gate layer 212 and the fins 210. The STI 216 may include one or more materials commonly employed for STIs in semiconductor devices. In some examples, the STI 216 may include various insulative materials such as, for example, silicon dioxide (SiO₂). The dummy fins 218 may include one or more materials commonly employed for dummy fins in semiconductor devices. In some examples, the dummy fins 218 may include the same or different materials than the fins 210. In some examples, the dummy fins 218 may include one or more layers of insulating materials such as, but not limited to, silicon nitride (Si₃N₄). The hard mask layer 214 may include one or more materials commonly employed for hard masks in semiconductor devices. In some examples, the hard mask layer 214 may include various insulative materials such as, for example, silicon nitride (Si₃N₄) or silicon monoxide (SiO).

At 114, the method 100 includes designating a region of the semiconductor device to form a fin-insulating structure. The region may be designated to separate various active regions of the semiconductor device. In FIG. 3, a region 211 is represented that generally designates a location for a fin-insulating structure that will be produced at a later stage in the method 100.

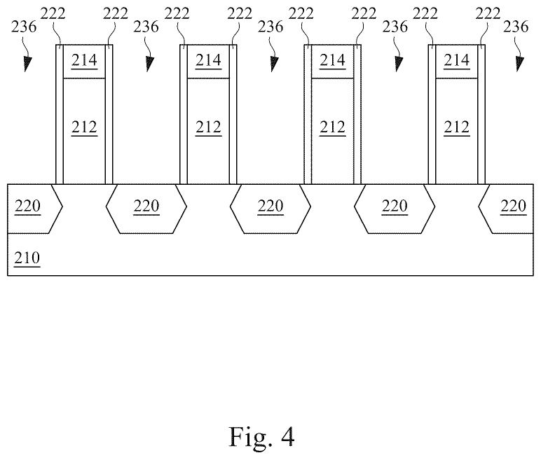

As noted above, seam-isolating structures are to be formed around the region 211 prior to forming the fin-insulating structures. However, in some examples, other features of the semiconductor structure may be formed prior to forming the seam-isolating structures. For example, the method 100 may include forming source/drain structures, ILDs, etc. FIGS. 4-7 illustrate an exemplary process for forming various features in the semiconductor structure prior to forming the seam-isolating structures.

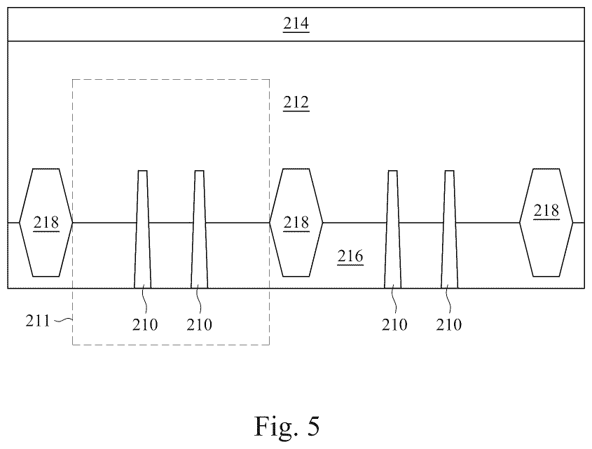

In FIGS. 4-5, trenches 236 have been formed in the semiconductor structure by removing portions of the dummy sacrificial gate layer 212 and the fins 210. In some examples, the portions of the dummy sacrificial gate layer 212 and the fins 210 may be removed with lithography and etching processes, as previously described. Cavities in the fins 210 at the base of the trenches 236 have been filled to form the source/drain structures 220.

Etch stop layers 222 may be formed on walls of the trenches 236 defined by adjacent portions of the hard mask layer 214 and the dummy sacrificial gate layer 212. In some examples, the etch stop layers 222 may be formed by a deposition process, such as chemical vapor deposition (CVD) (e.g., plasma enhanced chemical vapor deposition (PECVD), high aspect ratio process (HARP), or combinations thereof) process, atomic layer deposition (ALD) process, another applicable process, or combinations thereof. The etch stop layers 222 may be formed of materials that are resistant to an etchant used to remove other materials of the semiconductor structure in subsequent steps of the method 100 discussed in more detail below. In some examples, the etch stop layer 222 may include or be formed of silicon oxide (SiO) based low K material.

At the base of the trenches 236, source/drain structures 220 may be formed using, for example, an epitaxial layer growth process on exposed portions of the fins 210. In some examples, the epitaxial layer growth process may include depositing a thin layer of a semiconductor material on the surface of the fins 210 such as, but not limited to, silicon germanium (SiGe) or other materials with properties suitable for enhancing transistor performance. A chemical vapor deposition (CVD) process may be used for epitaxial growth. The CVD process may include introducing precursor gases containing the desired semiconductor elements into a reaction chamber at elevated temperatures. These gases decompose and react on the surface, leading to the deposition of a crystalline semiconductor layer. Depending on the specific transistor to be produced, dopant atoms may be introduced during epitaxial growth to achieve the desired electrical properties of the source/drain regions. Dopants such as phosphorus, arsenic, or boron may be used to control the conductivity and carrier concentration in the epitaxial layer. After epitaxial growth, an annealing process may be performed to improve crystal quality and activate dopants in the epitaxial layer.

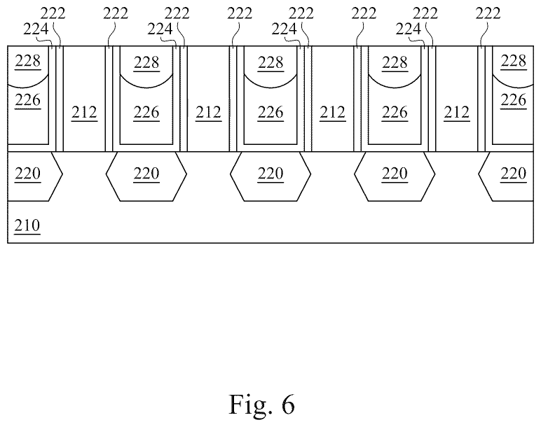

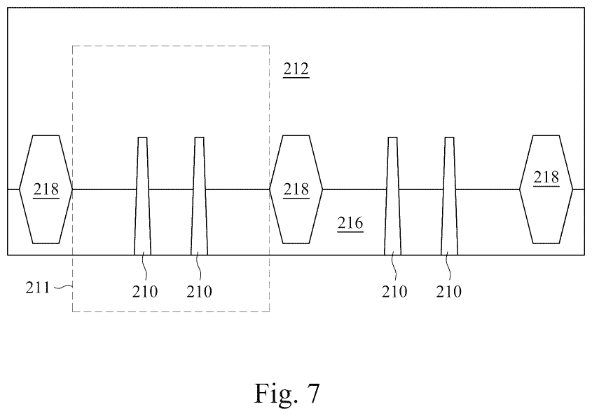

In FIGS. 6-7, the trenches 236 may be filled with a spacer layer 224, an ILD layer 226, and a hard mask layer 228. In some examples, the spacer layer 224 may include or be formed of one or more materials commonly employed for spacers in semiconductor devices, such as, silicon oxide, silicon nitride, or silicon carbide based materials. In some examples, the ILD layer 226 may include or be formed of one or more materials commonly employed for ILD layers in semiconductor devices. In some examples, the ILD layer 226 may include various dielectric materials including silicon oxide, phosphosilicate glass (PSG), borosilicate glass (BSG), boron-doped phosphosilicate glass (BPSG), undoped silicate glass (USG), or combinations thereof. In some examples, the hard mask layer 228 may include one or more materials commonly employed for hard masks in semiconductor devices. In some examples, the hard mask layer 228 may include various insulative materials such as, for example, silicon nitride (Si₃N₄) or silicon monoxide (SiO). The spacer layer 224, the ILD layer 226, and the hard mask layer 228 may each be formed by various processes, such as certain deposition processes. A chemical mechanical polishing (CMP) process may be performed to remove the remainder of the hard mask layer 228.

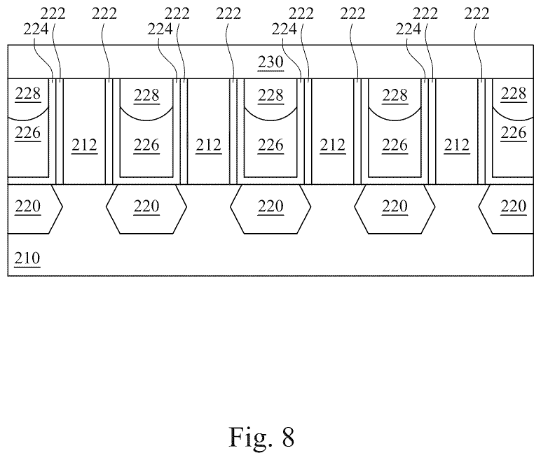

At 116, the method 100 may include forming seam-isolating structures around the region (e.g., the region 211) designated for the fin-insulating structure. Various methods may be used to form the seam-isolating structures. FIGS. 8-13 illustrate an exemplary process for forming seam-isolating structures in the semiconductor structure.

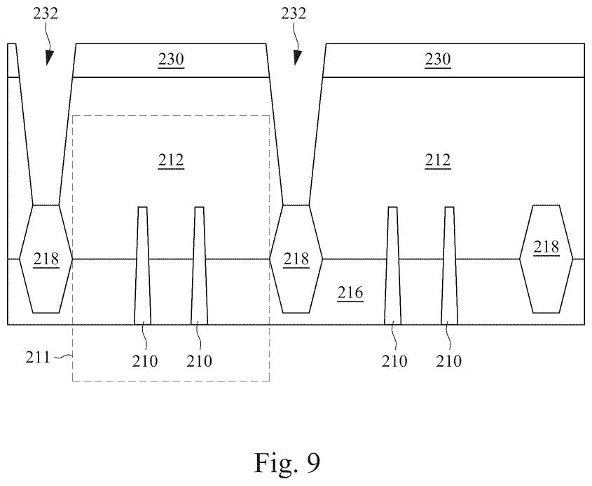

In FIGS. 8-9, a hard mask layer 230 is formed on the semiconductor structure. In some examples, the hard mask layer 230 may include various insulative materials such as, for example, silicon nitride (Si₃N₄) or silicon monoxide (SiO). A patterning process (e.g., Cut Poly), has been performed to form trenches 232 that extend through the hard mask layer 230, through the dummy sacrificial gate layer 212, and expose portions of the dummy fins 218 disposed on opposite sides of the region 211, enabling the patterning of gates and formation of seam-isolating structures for CMODE processes at the same time. In some examples, the dummy fins 218 may be omitted and the trenches 232 may extend to the STI 216.

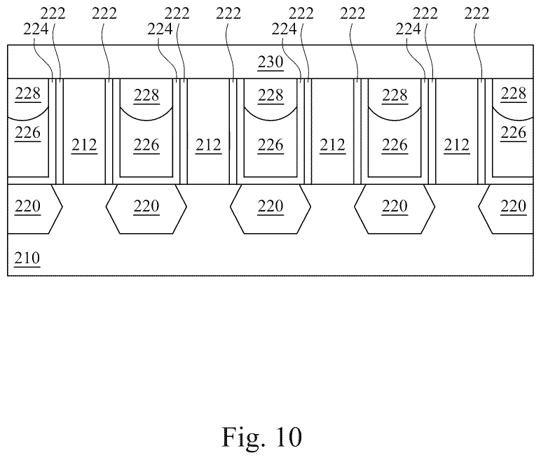

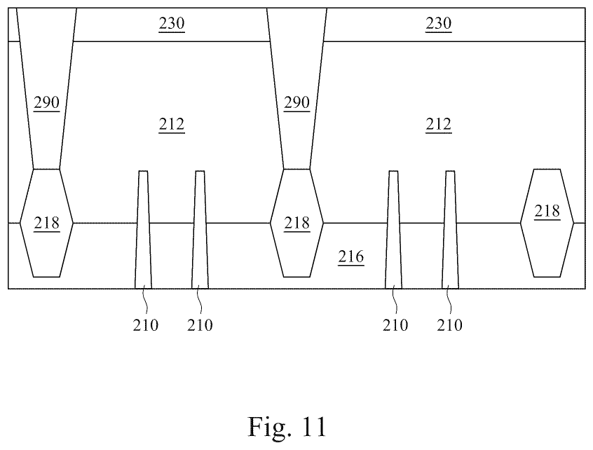

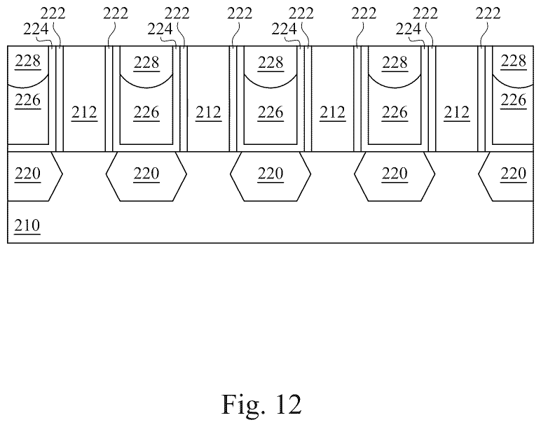

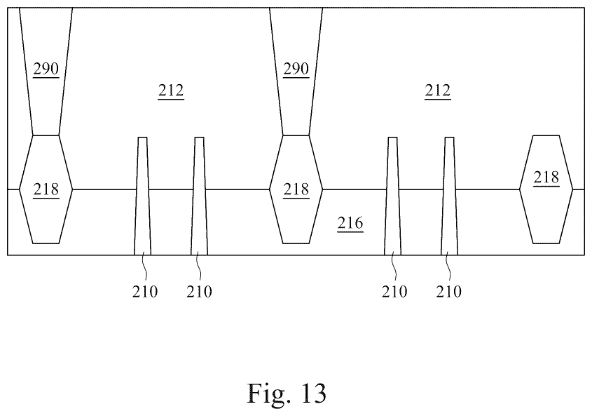

In FIGS. 10-11, the trenches 232 are filled to form the seam-isolating structures 290. The seam-isolating structures 290 may include or be formed of one or more dielectric materials such as, but not limited to, silicon nitride, silicon oxynitride, silicon carbonitride, silicon carbide, silicon oxycarbide, the like, or combinations thereof. In some examples, the seam-isolating structures 290 may be formed of or include the same materials as the hard mask layer 230. In FIGS. 12 and 13, a CMP process has been performed to remove the hard mask layer 230.

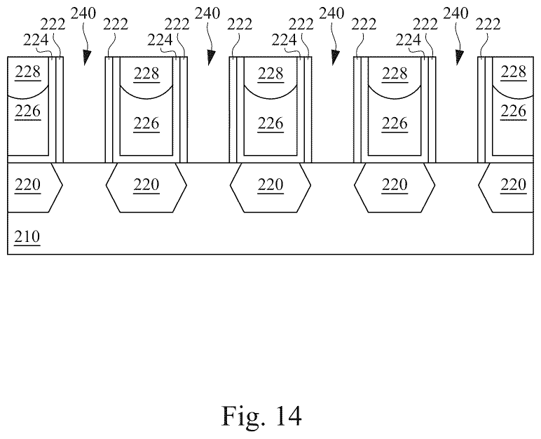

After forming the seam-isolating structures 290 and prior to forming the fin-isolation features, other features of the semiconductor device may be formed such as, but not limited to, gate structures. FIGS. 14-19 illustrate an exemplary process for gate structures in the semiconductor structure.

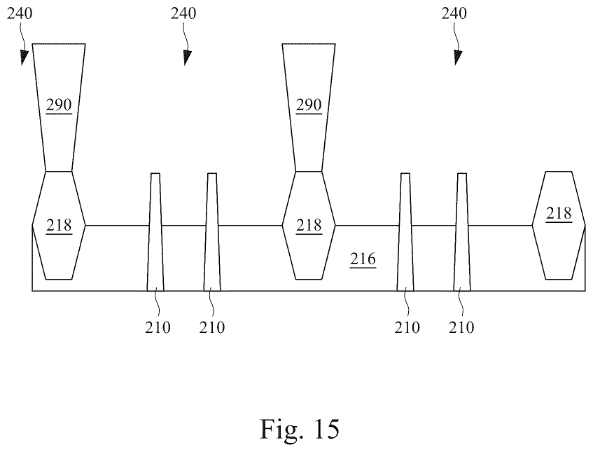

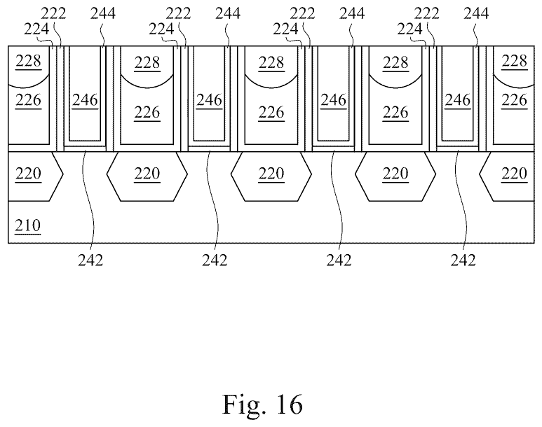

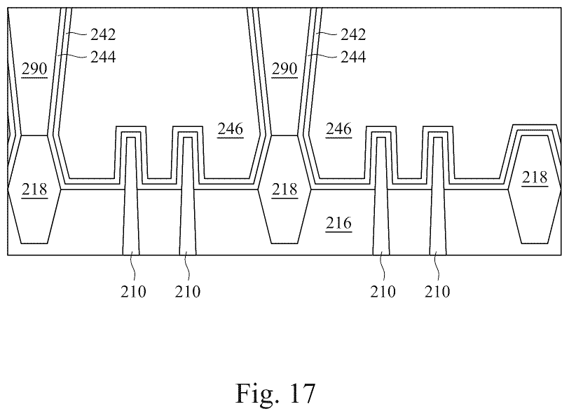

In FIGS. 14-15, trenches 240 are formed by removal of the dummy sacrificial gate layer 212 to expose portions of the fins 210, the STI 216, and the dummy fins 218. In some examples, removal of the insulation layer 212 may be performed with an etching process. In FIGS. 16-17, the trenches 240 have been filled by forming various layers of the gate structures therein, such as a first and second gate spacers 242 and 244, and a metal gate layer 246. In some examples, the first and second gate spacers 242 and 244 may include a single conformal layer or a combination of two or more conformal layers. In some examples, the first gate spacers 242 may include a dielectric material such as, but not limited to, silicon based dielectrics, such as, silicon nitride, silicon oxynitride, silicon carbonitride, silicon carbide, silicon oxycarbide, and the like. In some example, the second gate spacers 244 may include a high k dielectric material, such as, but not limited to, hafnium oxide, aluminum oxide, lanthanum oxide, zirconium oxide, and the like. In some examples, a combination of the first and second gate spacers 242 and 244 with opposite or repeated order may be employed.

In some examples, the metal gate layer 246 may be formed of one or more metal material layers. For example, the metal gate layer 246 may be a p-type work function layer, an n-type work function layer, multi-layers thereof, or combinations thereof. The work function layer may also be referred to as a work function metal. Example p-type work function metals that may include TIN, TAN, Ru, Mo, Al, WN, ZrSi₂, MoSi₂, TaSi₂, NiSi₂, WN, other suitable p-type work function materials, or combinations thereof. Example n-type work function metals that may include Ti, Ag, TaAl, TaAlC, TiAlN, TAC, TACN, TaSiN, Mn, Zr, other suitable n-type work function materials, or combinations thereof.

The first and second gate spacers 242 and 244, and the metal gate layer 246 may be formed with various processes, such as certain deposition processes. CMP processes may be used as needed between the formation processes.

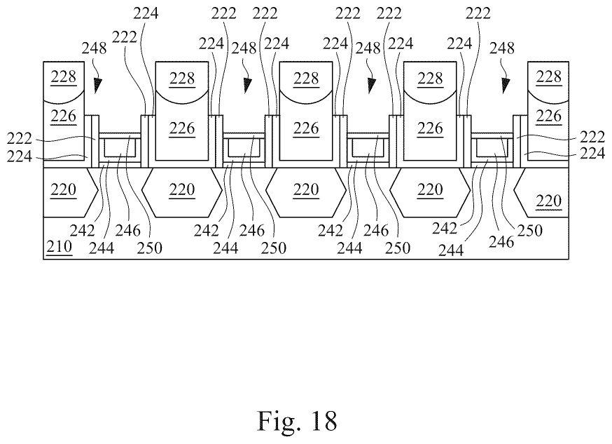

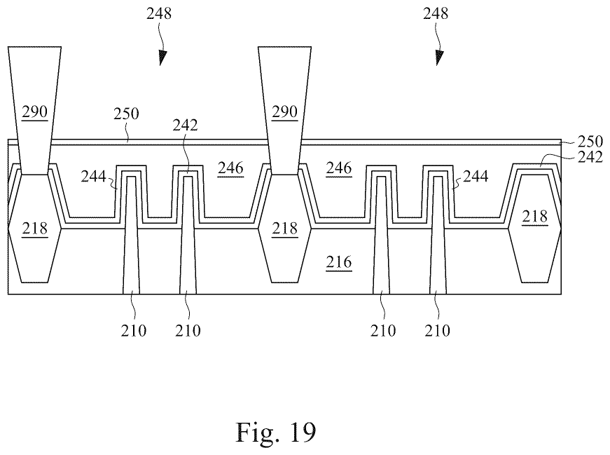

In FIGS. 18-19, trenches 248 are formed by removal of portions of the layers of the gate structures to achieve desired dimensions of the gate structures. In some examples, the removal may be performed with a metal gate etch back process. Optionally, a metallic layer 250 may be selectively formed on exposed portions of the metal gate layer 246. Portions of the etch stop layers 222 and the spacer layers 224 may be removed to expose portions of the ILD layer 226 and the hard mask layer 228. Portions of the seam-isolating structures 290 may also be exposed.

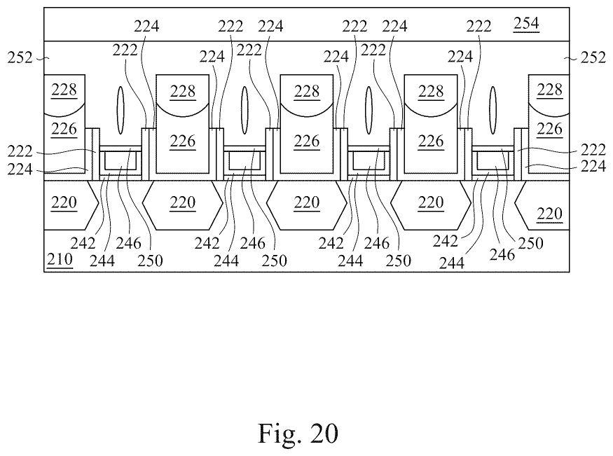

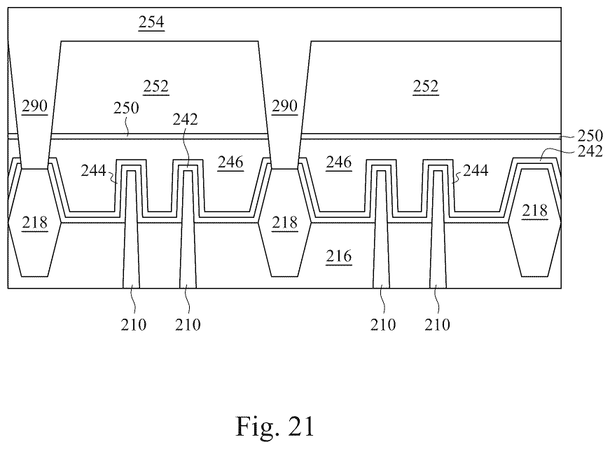

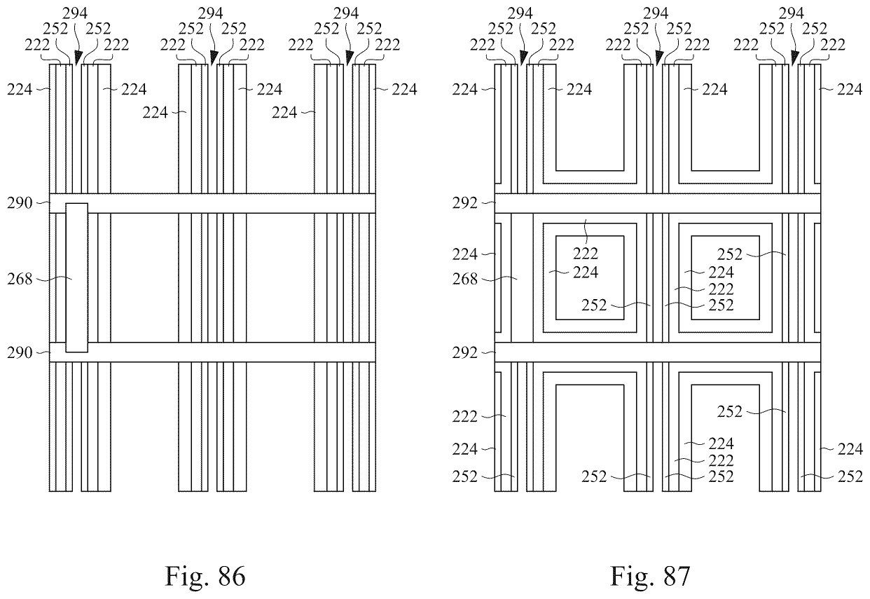

At 118, the method 100 includes forming SAC sacrificial material layers. In FIGS. 20-21, the trenches 248 are filled with a SAC sacrificial material layers 252. The SAC sacrificial material layers 252 may be formed by various processes, such as certain deposition processes. The SAC sacrificial material layer 252 may include or be formed of one or more materials commonly used for SAC sacrificial materials in semiconductor devices. In some examples, the SAC sacrificial material layer 252 may include or be formed of amorphous silicon. A hard mask layer 254 may be formed to overlay the SAC sacrificial material layer 252 and the seam-isolating structures 290. The hard mask layer 254 may include one or more materials commonly employed for hard masks in semiconductor devices. In some examples, the hard mask layer 214 may include various insulative materials such as, for example, silicon nitride (Si₃N₄), silicon oxide (SiO₂), or silicon. As represented in FIG. 20, the SAC sacrificial material layer 252 may include seams (e.g., 294 in FIGS. 86 and 87) extending through the semiconductor structure over the gate structures.

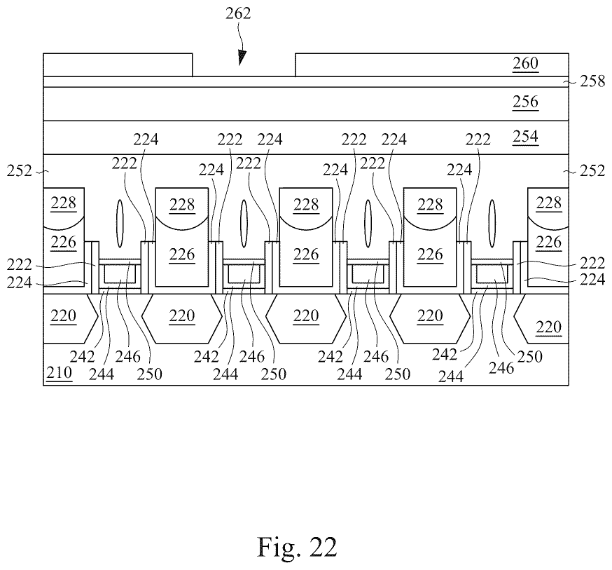

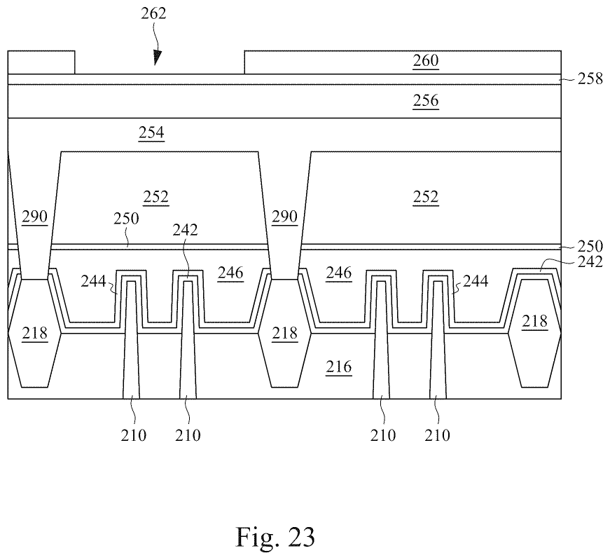

At 120, the method 100 includes forming the fin-insulating structures between the seam-isolating structures 290. FIGS. 22-33 illustrate exemplary processes for forming the fin-insulating structures in the semiconductor structure. In FIGS. 22-23, a photoresist layer 260, a middle layer 258, and a bottom layer 256 have been formed to overlay the hard mask layer 254. A trench 262 has been formed in the photoresist layer 260 that exposes the middle layer 258 and that is aligned with the region 211 designated for the fin-insulating structure. FIG. 8 is a perspective view of the semiconductor structure at the manufacturing stage represented in FIGS. 22-23 with the ILD layer 226 presented as partially transparent for ease of observing the other layers.

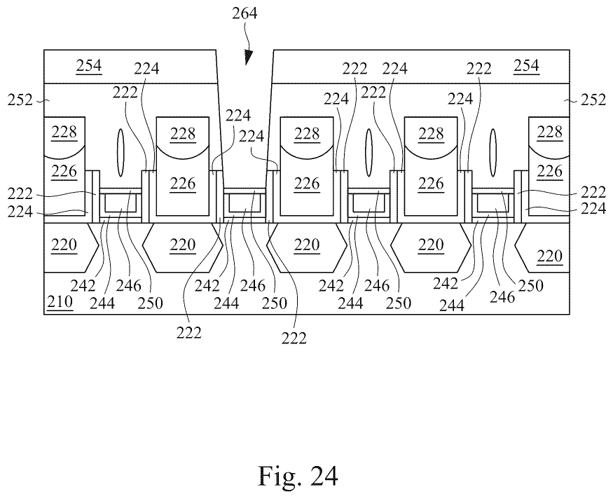

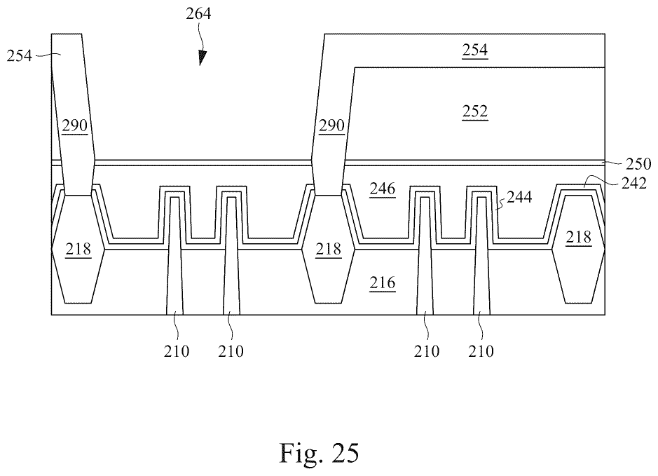

In FIGS. 24-25, lithography and etching processes have been performed to extend the trench 262 through the middle layer 258, the bottom layer 256, the hard mask layer 254, and portions of the SAC sacrificial material layer 252 to define trenches 264 and expose the metallic layer 250 overlying one of the gate structures disposed below the trench 264. The photoresist layer 260, the middle layer 258, and the bottom layer 256 are removed. Notably, at least some of the sidewalls of the trench 264 are defined by the seam-isolating structures 290 such that the trench 264 does not have access to the seams within the SAC sacrificial material layers 252, that is, the trench 264 is not in fluidic communication with the seams adjacent thereto.

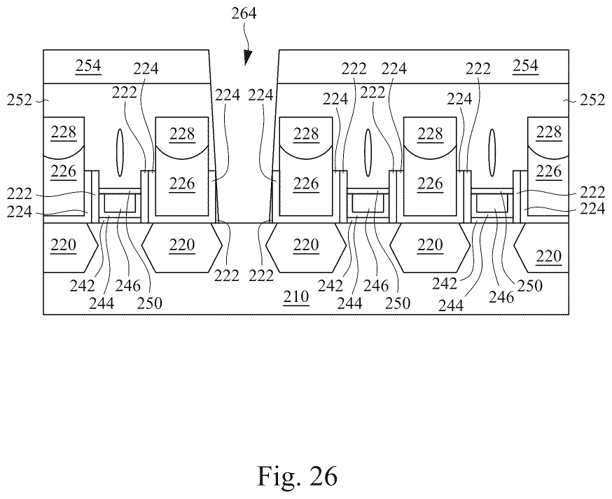

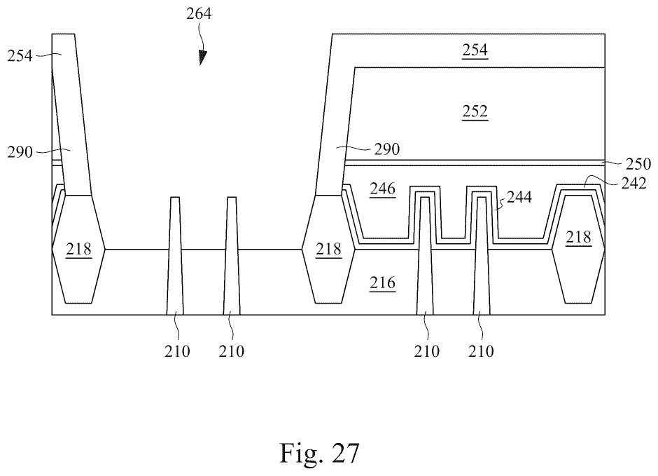

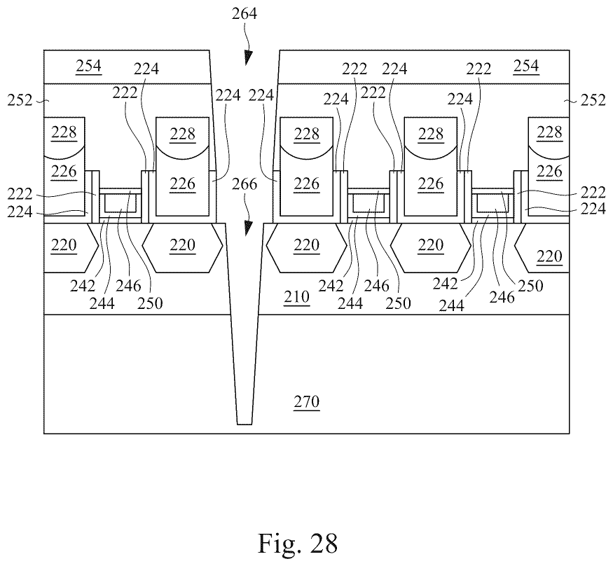

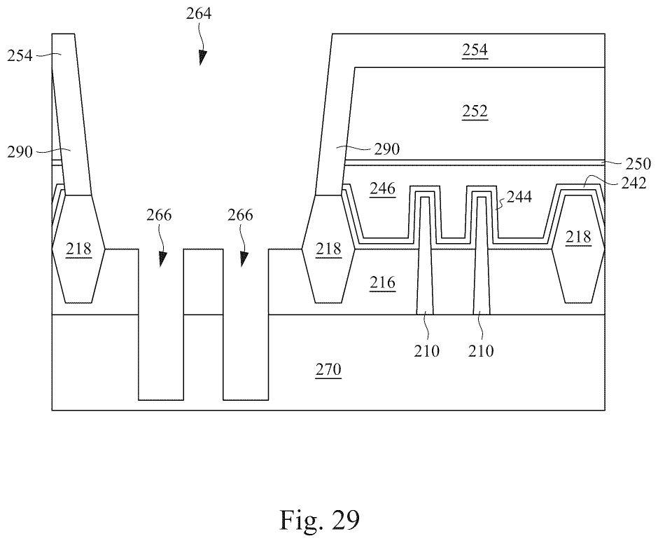

In FIGS. 26-27, another etching process has been performed to remove the gate structure exposed by the trench 264 and to expose the fins 210 and portions of the STI 216 therebelow. In FIGS. 28 and 29, another etching process may be performed to remove the fins 210 within the region 211 designated for the fin-insulating structure and portions of the STI 216 and the substrate 270 adjacent thereto. Removal of the fins 210 and adjacent materials extends the trench 264 to define additional trenches 266.

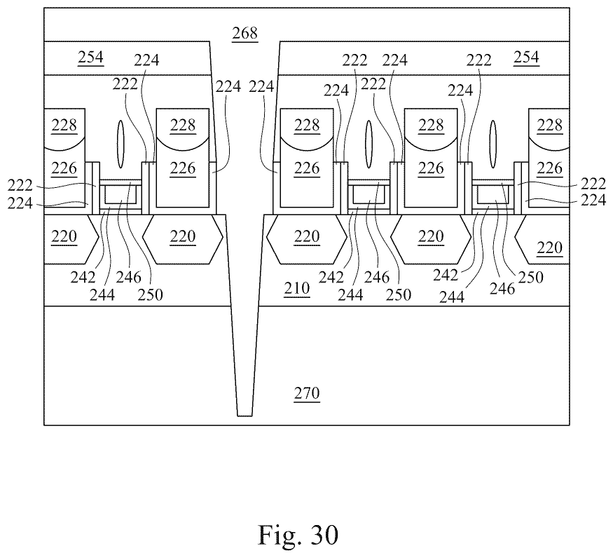

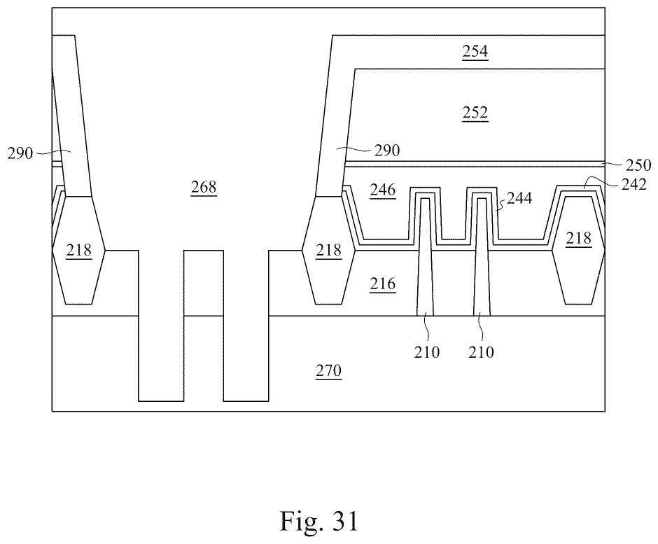

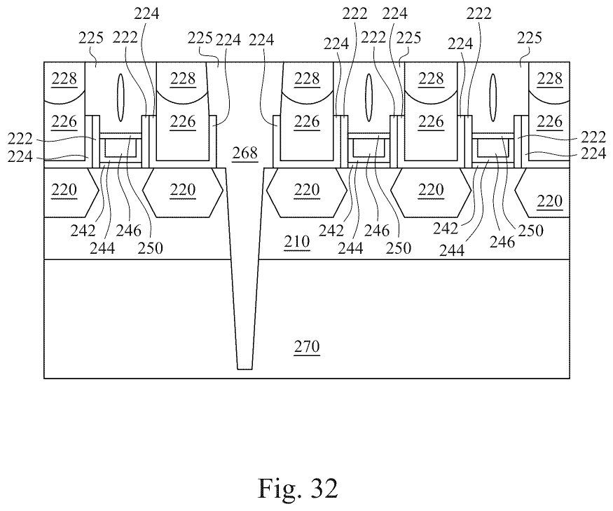

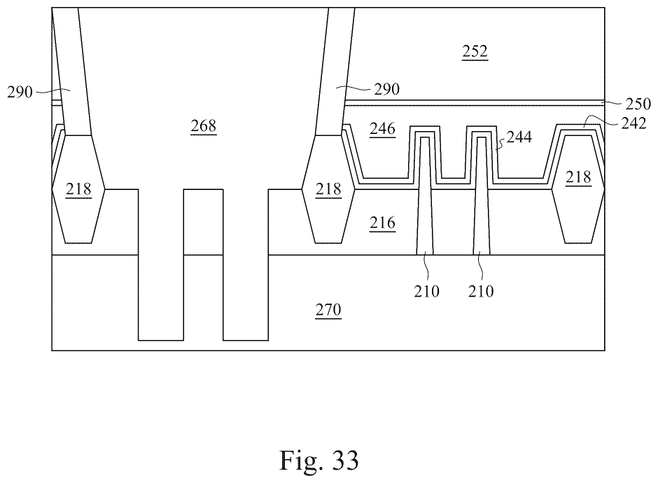

In FIGS. 30-31, a CMODE refill process has been performed to fill the trenches 264 and 266 to form the fin-insulating structure 268. The fin-insulating structure 268 may be formed of a CMODE refill material, such as a low k material or dielectric material. Notably, the CMODE refill material does not flow or diffuse into the seams of the SAC sacrificial material layer 252 since the CMODE refill material is constrained by the seam-isolating structures 290. In FIGS. 32-33, a CMP is performed to remove excess portions of the fin-insulating structure 268, the hard mask layer 254, and portions of the SAC sacrificial material layer 252 sufficient to expose the hard mask layers 228. FIG. 86 is a top view schematically representing some of the layers of the semiconductor structure at the manufacturing stage represented in FIGS. 32-33 (other layers and features are omitted for clarity). From this perspective, it is clear that the seam-isolating structures 290 block the seams of the SAC sacrificial material layer 252 and thereby prevent or reduce the likelihood of the CMODE refill material (or any other undesired material) flowing or diffusing into the seams.

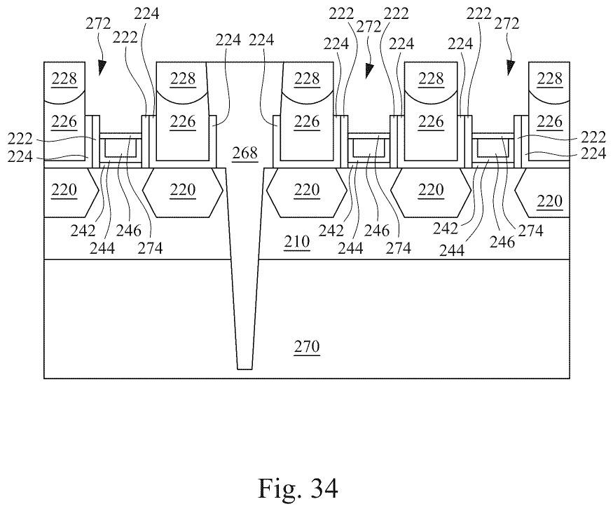

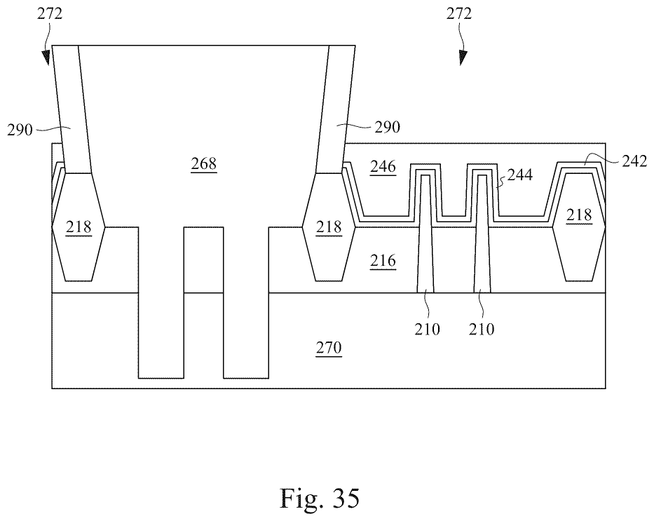

At 122, the method 100 includes removing the SAC sacrificial material layers. In FIGS. 34-35, the SAC sacrificial material layer 252 has been removed to define trenches 272 and expose the gate structures there below and portions of the etch stop layers 222 and the spacer layers 224.

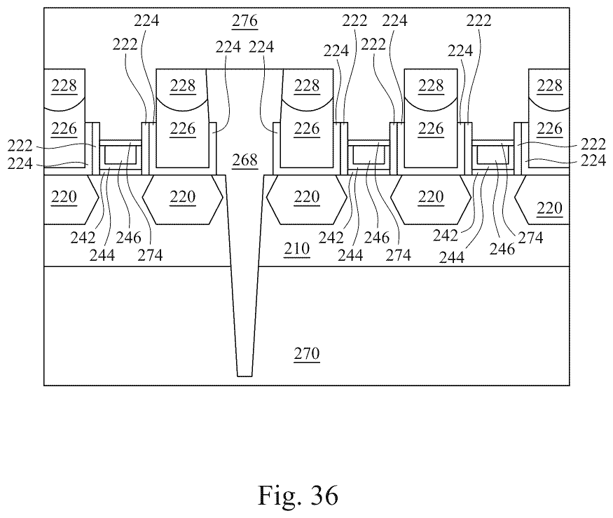

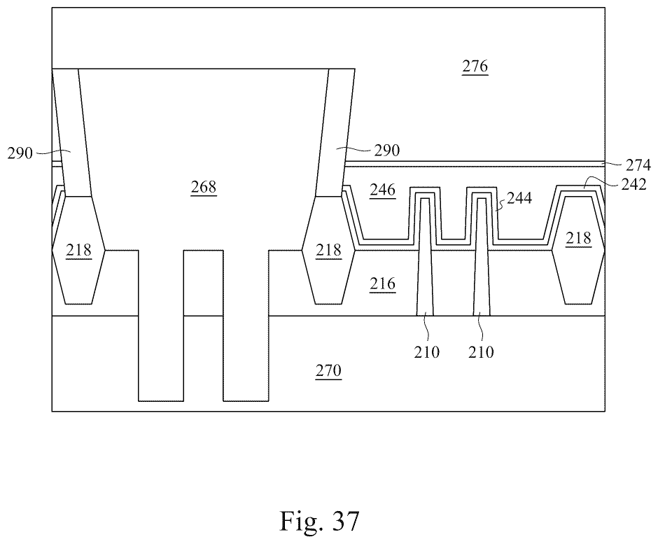

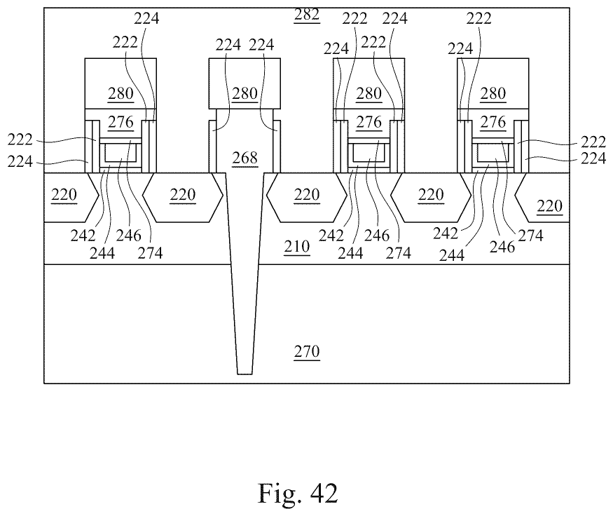

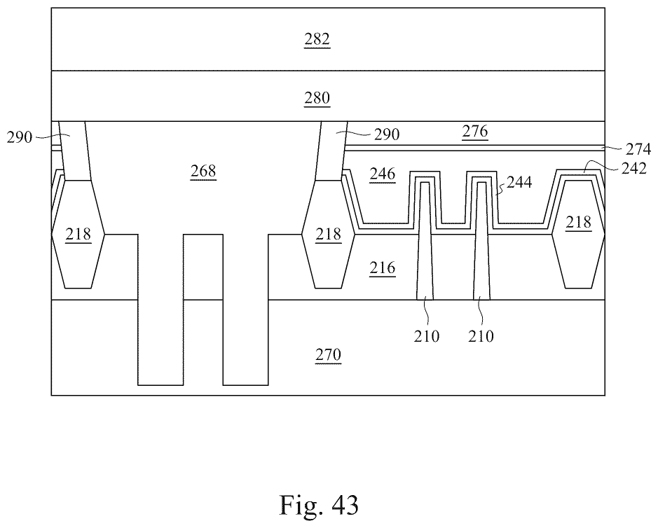

At 124, the method 100 includes performing a SAC process to form source/drain contacts. FIGS. 36-45 illustrate exemplary processes for forming the source/drain contacts in the semiconductor structure. In FIGS. 36-37, the trenches 272 have been filled with an SAC insulating material layer 276 that overlies the gate structures, the hard mask layers 228, the seam-isolating structures 290, and the fin-insulating structures 268. In some examples, the SAC insulating material layer 276 may include silicon nitride (SiN). In some examples, a metal contact layer 274 may be formed on the gate structures prior to forming the SAC insulating material layer 276. The metal contact layer 274 may include conductive materials such as tungsten (W) or cobalt (Co).

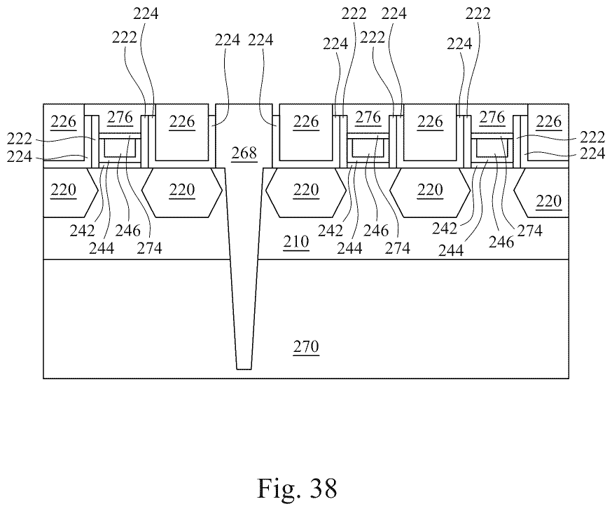

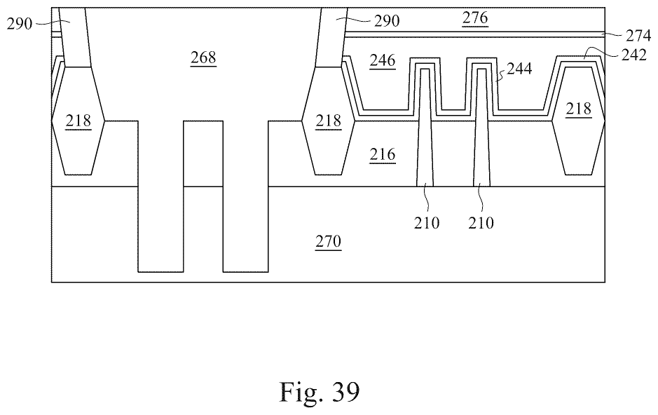

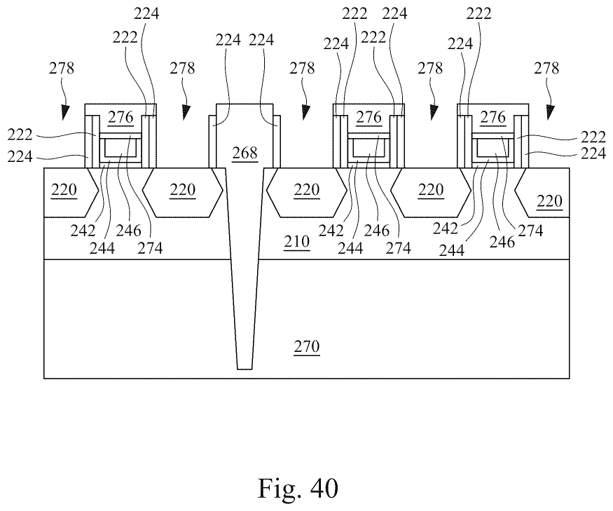

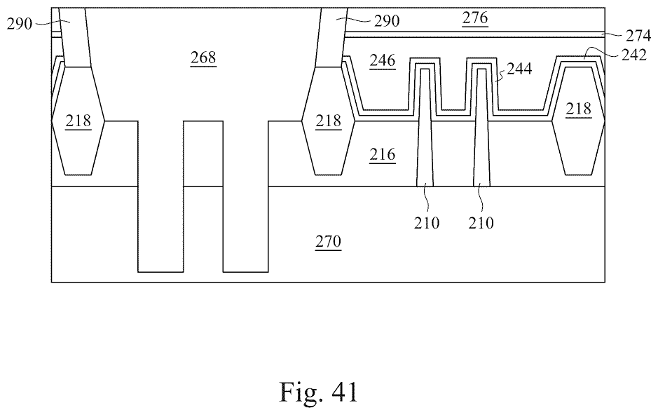

In FIGS. 38-39, a CMP process has been performed to remove excess portions of the SAC insulating material layer 276 and the hard mask layers 228 to expose the ILD layers 226. In FIGS. 40-41, an etching process has been performed to remove the ILD layers 226, form trenches 278, and expose portions of the source/drain structures 220.

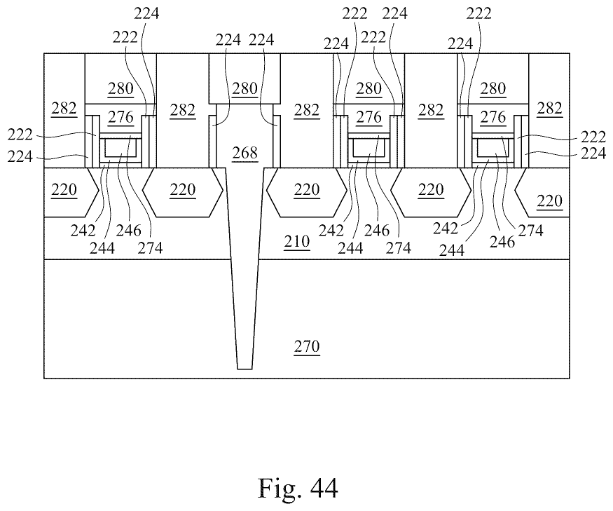

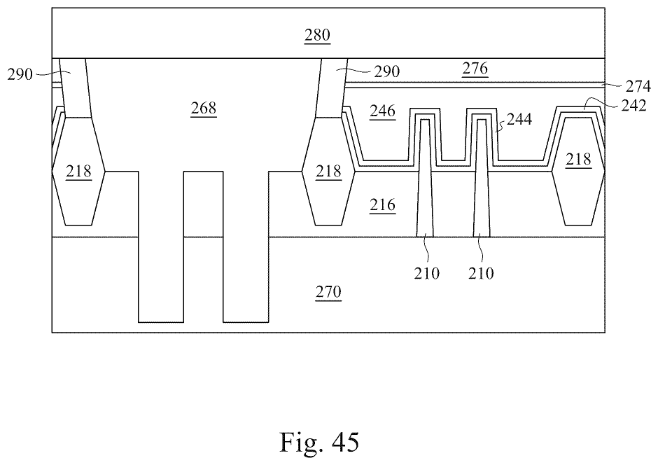

In FIGS. 44-45, a dielectric layer 280 has been formed over the SAC insulating material layer 276 and the trenches 278 have been filled with a conductive layer 282. In some embodiments, silicide may be formed between the conductive layer 282 and the source/drain structures 220 to lower the contact resistance between metal and source or drain. The dielectric layer 280 may include or be formed of various dielectric materials, and may be formed by various deposition, lithography, and etching processes. Although represented as a single layer, the conductive layer 282 may include two or more layers to avoid metal migration into dielectric layers. For example, the conductive layer 282 may include a fill material and a liner. In some embodiments, the layers may include a liner formed of a noble metal or alloy thereof such as, but not limited to, rhenium (Re), rhodium (Rh), ruthenium (Ru), or alloys thereof. In some embodiments, the layers may include a fill material formed of copper (Cu), aluminum (Al), tungsten (W), silver (Ag), or alloys thereof. The conductive layer 282 may be formed by various deposition processes. In FIGS. 44-45, a CMP process has been performed to remove excess material of the conductive layer 282 and thereby define source/drain contacts over the source/drain structures 220.

The method 100 may end at 126.

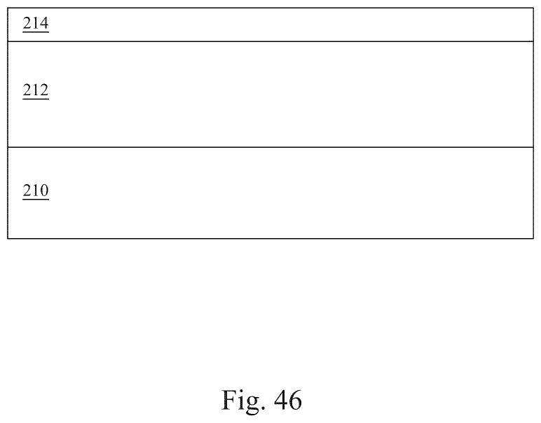

FIGS. 46-85 illustrate an alternative process for forming seam-isolating structures in the semiconductor structure. For convenience, consistent reference numbers are used throughout FIGS. 2-85 to identify the same or functionally related/equivalent elements. In view of similarities between the examples, the following discussion of FIGS. 46-85 will focus primarily on aspects of the examples that differ from the other examples in some notable or significant manner. Other aspects of the examples not discussed in any detail can be, in terms of structure, function, materials, etc., essentially as was described for one or more of the other examples, including the example of FIGS. 2-45.

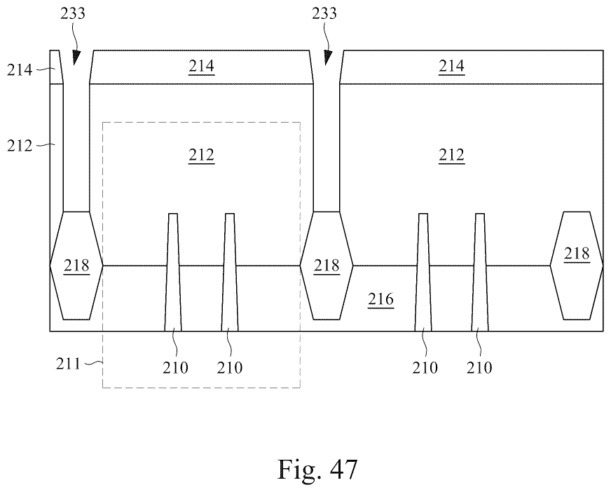

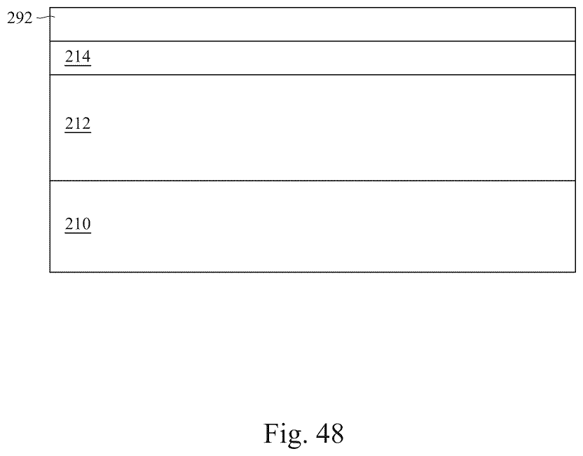

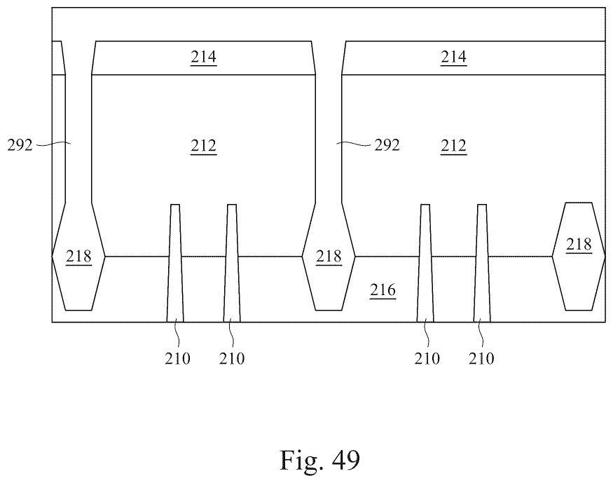

Initially, the semiconductor structure may have the same structure as represented in FIGS. 2 and 3. In FIG. 47, a region 211 is represented that generally designates a location for a fin-insulating structure. Unlike the example of FIGS. 2-45, in this example the seam-isolating structures may be formed prior to other features of the semiconductor structure. Therefore, in FIGS. 46-47, trenches 233 have been formed by removing portions of the hard mask layer 214 and the dummy sacrificial gate layer 212 to expose portions of the dummy fins 218. In some examples, the portions of the hard mask layer 214 may be removed with, for example, lithography and etching processes. In FIGS. 48-49, the trenches 233 have been filled with an insulating material to extend the dummy fins 218 to define extended dummy fins 292. In some examples, the insulating material may be the same material from which the dummy fins 218 are formed. A CMP process may be performed to remove the hard mask layer 214 and excess portions of the extended dummy fins 292. In this example, the extended dummy fins 292 define the seam-isolating structures and may be considered to extend from the dummy fins 218 or be integral with the dummy fins 218 and therefore extend from the STI 216.

FIGS. 50-53 illustrate an exemplary process for forming the source/drain structures 220, spacer layer 224, the ILD layers 226, and the hard mask layer 228. In some examples, the source/drain structures 220, spacer layer 224, the ILD layers 226, and the hard mask layers 228 may be formed in accordance with the description of FIGS. 4-7.

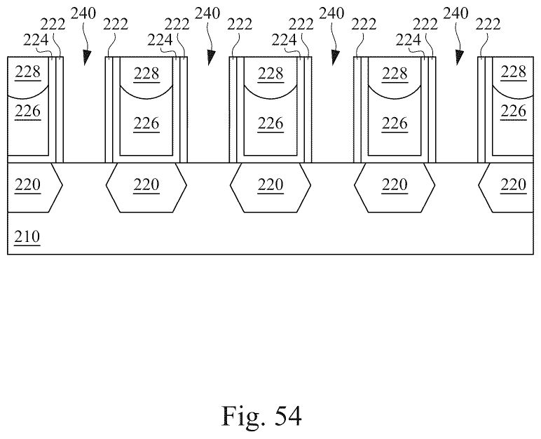

FIGS. 54-59 illustrate an exemplary process for forming gate structures in the semiconductor structure. In some examples, the gate structures may be formed in accordance with the description of FIGS. 14-19.

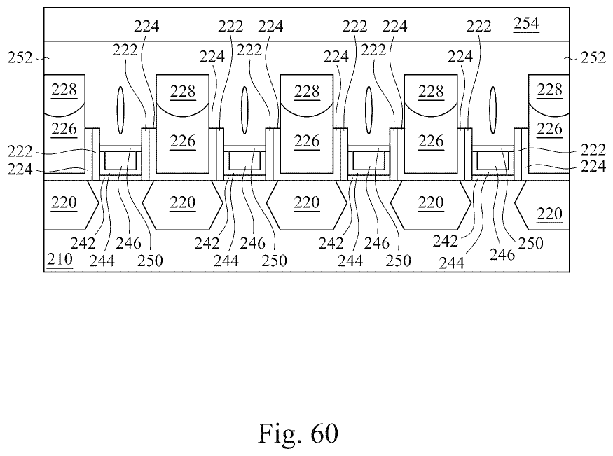

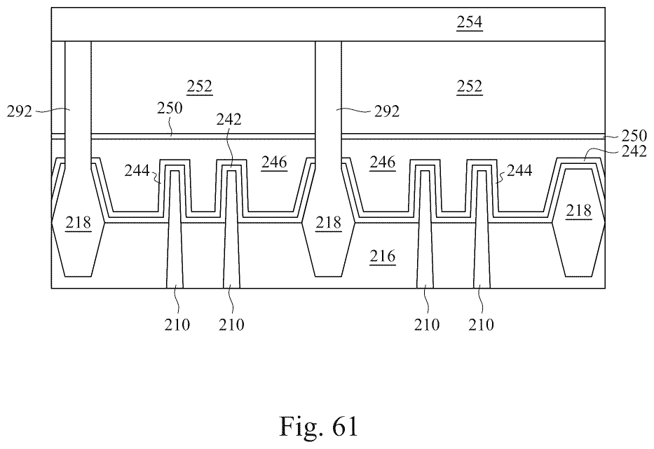

FIGS. 60-61 illustrate an exemplary process for forming the SAC sacrificial material layers 252 in the semiconductor structure. In some examples, the SAC sacrificial material layers 252 may be formed in accordance with the description of FIGS. 20-21.

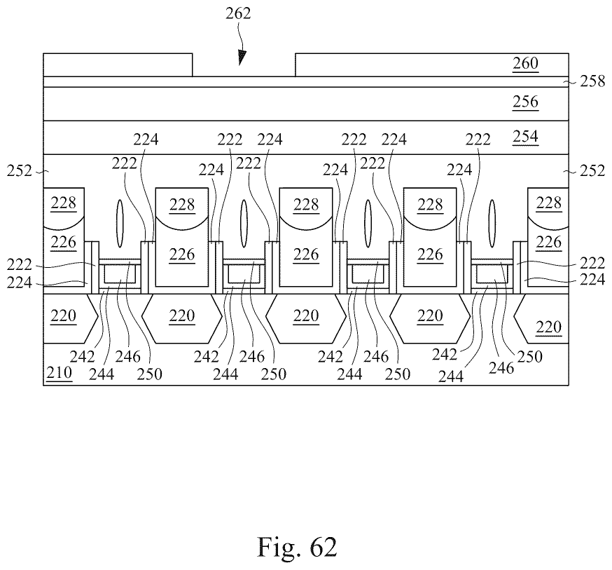

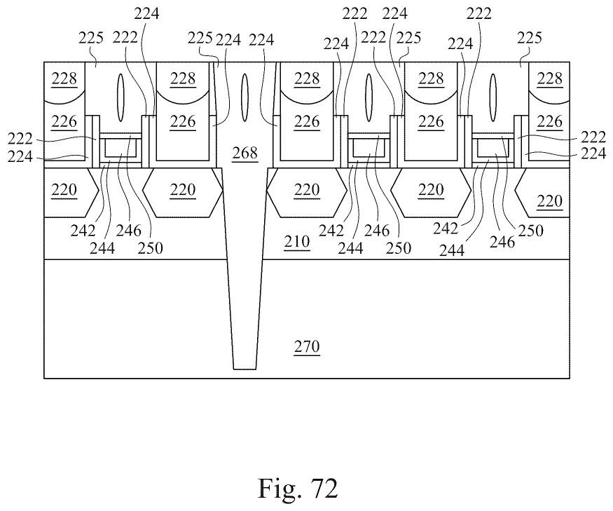

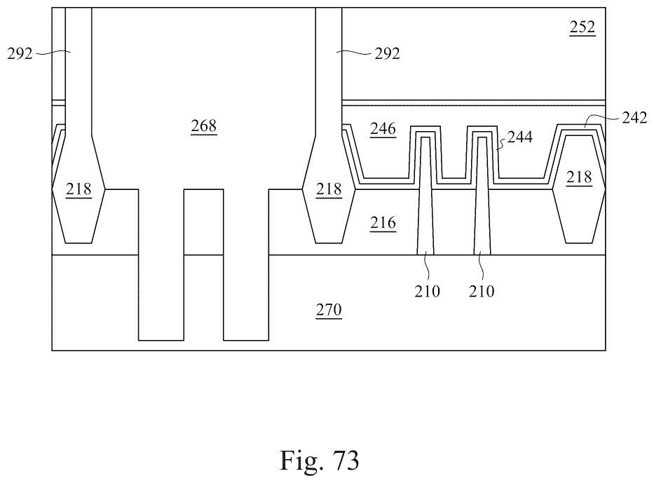

FIGS. 62-73 illustrate exemplary processes for forming the fin-insulating structures in the semiconductor structure. In some examples, the fin-insulating structures may be formed in accordance with the description of FIGS. 22-33. FIG. 87 is a top view schematically representing some of the layers of the semiconductor structure at the manufacturing stage represented in FIGS. 72-73 (other layers and features are omitted for clarity). From this perspective, it is clear that the extended dummy fins 292 block the seams of the SAC sacrificial material layer 252 and thereby prevent or reduce the likelihood of the CMODE refill material (or any other undesired material) flowing or diffusing into the seams.

In the examples of FIGS. 2-45, the semiconductor structure included the seam-isolating structures 290 formed overlaying the dummy fins 218, and in the examples of FIGS. 46-73, the semiconductor structure included the extended dummy fins 292 overlaying the dummy fins 218. However, in some examples, the dummy fins 218 may be omitted and the methods illustrated and described in FIGS. 2-73 may be performed with the seam-isolating structures 290 or the extended dummy fins 292 being formed to directly contact the STI 216.

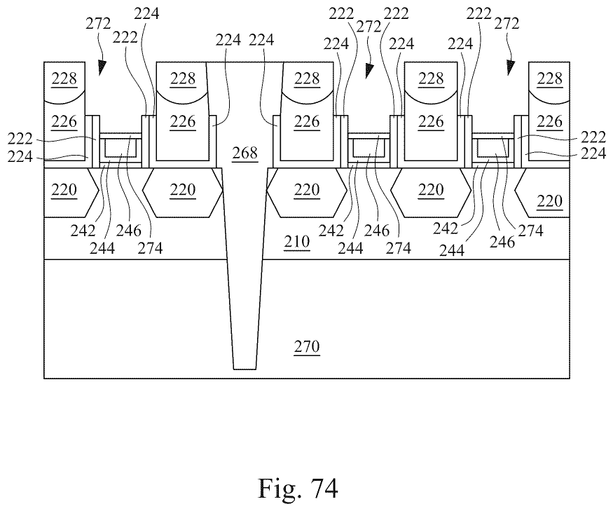

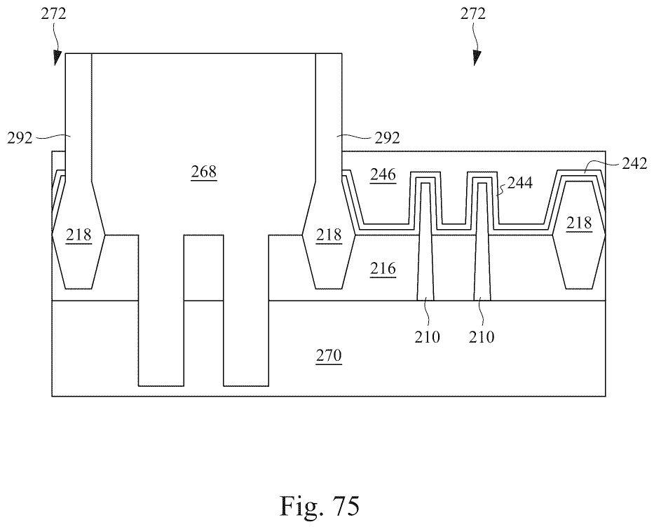

FIGS. 74-75 illustrate exemplary processes for removing the SAC sacrificial material layer 252. In some examples, the SAC sacrificial material layer 252 may be removed in accordance with the description of FIGS. 34-35.

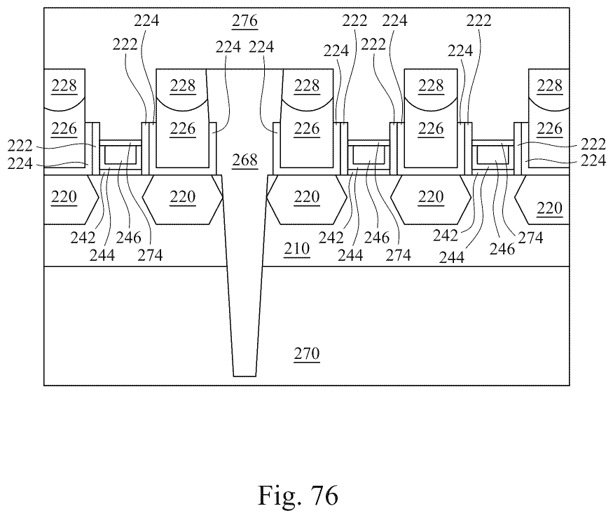

FIGS. 76-85 illustrate exemplary processes for forming the source/drain contacts in the semiconductor structure. In some examples, the source/drain contacts may be formed in accordance with the description of FIGS. 36-45.

The present disclosure therefore provides semiconductor devices and methods for manufacturing the same that may significantly reduce a likelihood of defects in the semiconductor devices. In some embodiments, the semiconductor devices include seam-isolating structures configured to reduce a likelihood of material flowing or diffusion into SAC sacrificial material during a CMODE process.

In accordance with an embodiment, a semiconductor device is provided that includes a substrate, a fin overlying the substrate and providing active regions for at least two devices, a fin-insulating structure positioned to electrically isolate the active regions for the at least two devices, wherein the fin-insulating structure extends through the fin and into the substrate, wherein the fin-insulating structure includes a dielectric material, and a pair of seam-isolating structures positioned adjacent to the fin on oppositely disposed sides thereof, wherein the seam-isolating structures define boundaries of the fin-insulating structure on sides of the fin.

In accordance with another embodiment, a method is provided for manufacturing a semiconductor device. The method includes providing a substrate, forming a fin overlying the substrate, forming seam-isolating structures positioned adjacent to the fin on oppositely disposed sides thereof, forming active regions for at least two devices on the fin, and forming a fin-insulating structure positioned to electrically isolate the active regions for the at least two devices, wherein the fin-insulating structure extends through the fin and into the substrate, wherein the fin-insulating structure includes a dielectric material, wherein the seam-isolating structures define boundaries of the fin-insulating structure on the sides of the fin.

In accordance with yet another embodiment, a method for manufacturing a semiconductor device. The method includes providing a substrate, forming a fin overlying the substrate, forming active regions for devices on the fin, forming seam-isolating structures positioned adjacent to the fin on oppositely disposed sides thereof, wherein the seam-isolating structure extends from a shallow trench isolation in a position adjacent to the fin, wherein the seam-isolating structure is formed of a dielectric material, forming gate structures between the active regions of the devices, forming a fin-insulating structure positioned to electrically isolate the active regions for at least two of the devices, wherein the fin-insulating structure extends through the fin and into the substrate, wherein the fin-insulating structure includes a dielectric material, wherein the seam-isolating structures define boundaries of the fin-insulating structure on the sides of the fin, and forming contacts electrically coupled with the active regions of the devices.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

1. A semiconductor device, comprising:
a substrate;
a fin overlying the substrate and providing active regions for at least two devices;
a fin-insulating structure positioned to electrically isolate the active regions for the at least two devices, wherein the fin-insulating structure extends through the fin and into the substrate, wherein the fin-insulating structure includes a first dielectric material; and
a pair of seam-isolating structures positioned adjacent to the fin on oppositely disposed sides thereof, wherein the seam-isolating structures define boundaries of the fin-insulating structure on the sides of the fin.

2. The semiconductor device of claim 1, wherein the seam-isolating structures are positioned at line ends of a metal gate line.

3. The semiconductor device of claim 1, wherein the fin-insulating structure directly contacts the seam-isolating structure with the fin-insulating structure.

4. The semiconductor device of claim 1, wherein the fin-insulating structure extends to between two opposing sidewalls of the seam-isolating structure, and the fin-insulating structure and the seam-isolating structure extend in different directions.

5. The semiconductor device of claim 1, wherein the seam-isolating structures overlay dummy fins adjacent to the fin, and the seam-isolating structures are formed of a first material that is different from a second material from which the dummy fins are formed.

6. The semiconductor device of claim 1, wherein the seam-isolating structures overlay dummy fins adjacent to the fin, and the seam-isolating structures and the dummy fins are formed of the same material.

7. The semiconductor device of claim 1, wherein the seam-isolating structures are formed of a second dielectric material.

8. A method for manufacturing a semiconductor device, the method comprising:
providing a substrate;
forming a fin overlying the substrate;
forming seam-isolating structures positioned adjacent to the fin on oppositely disposed sides thereof;
forming active regions for at least two devices on the fin; and
forming a fin-insulating structure positioned to electrically isolate the active regions for the at least two devices, wherein the fin-insulating structure extends through the fin and into the substrate, wherein the fin-insulating structure includes a first dielectric material, wherein the seam-isolating structures define boundaries of the fin-insulating structure on the sides of the fin.

9. The method of claim 8, further comprising:
forming self-aligning contact (SAC) sacrificial material layers after forming the seam-isolating structures and prior to forming the fin-insulating structure, wherein the seam-isolating structures are disposed between the SAC sacrificial material layers and the fin-insulating structure;
removing the SAC sacrificial material layers after forming the fin-insulating structure; and
performing a SAC process to form contacts electrically coupled with the active regions of the at least two devices.

10. The method of claim 8, wherein forming the seam-isolating structures includes positioning the seam-isolating structures at line ends of a metal gate line of the semiconductor device.

11. The method of claim 8, wherein the fin-insulating structure directly contacts the seam-isolating structure with the fin-insulating structure.

12. The method of claim 8, wherein the fin-insulating structure extends to between two opposing sidewalls of the seam-isolating structure, and the fin-insulating structure and the seam-isolating structure extend in different directions.

13. The method of claim 8, wherein the seam-isolating structures overlay dummy fins adjacent to the fin, and the seam-isolating structures are formed of a first material that is different from a second material from which the dummy fins are formed.

14. The method of claim 8, wherein the seam-isolating structures overlay dummy fins adjacent to the fin, and the seam-isolating structures and the dummy fins are formed of the same material.

15. The method of claim 8, wherein the seam-isolating structures are formed of a second dielectric material.

16. A method for manufacturing a semiconductor device, the method comprising:
providing a substrate;
forming a fin overlying the substrate;
forming active regions for devices on the fin;
forming seam-isolating structures positioned adjacent to the fin on oppositely disposed sides thereof, wherein the seam-isolating structures extend from a shallow trench isolation in a position adjacent to the fin, wherein the seam-isolating structures are formed of a first dielectric material;
forming gate structures between the active regions of the devices;
forming a fin-insulating structure positioned to electrically isolate the active regions for at least two of the devices, wherein the fin-insulating structure extends through the fin and into the substrate, wherein the fin-insulating structure includes a second dielectric material, wherein the seam-isolating structures define boundaries of the fin-insulating structure on the sides of the fin; and
forming contacts electrically coupled with the active regions of the devices.

17. The method of claim 16, further comprising:
forming self-aligning contact (SAC) sacrificial material layers after forming the seam-isolating structures and prior to forming the fin-insulating structure, wherein the seam-isolating structures are disposed between the SAC sacrificial material layers and the fin-insulating structure; and
removing the SAC sacrificial material layers after forming the fin-insulating structure,
wherein forming the contacts includes performing a SAC process.

18. The method of claim 16, wherein forming the seam-isolating structures includes positioning the seam-isolating structures at line ends of a metal gate line of the semiconductor device.

19. The method of claim 16, wherein the fin-insulating structure directly contacts the seam-isolating structure with the fin-insulating structure.

20. The method of claim 16, wherein the fin-insulating structure extends to between two opposing sidewalls of the seam-isolating structure, and the fin-insulating structure and the seam-isolating structure extend in different directions.
